(19) United States
(12) Patent Application Publication
(10) Pub. No.: US 2026/0105940 A1
(43) Pub. Date: Apr. 16, 2026

(54) SEMICONDUCTOR MEMORY DEVICE INCLUDING PAD BLOCK PATTERN

(71) Applicant: SAMSUNG ELECTRONICS CO., LTD., SUWON-SI (KR)

(72) Inventors: Tae Hyuk KIM, Suwon-si (KR); Suk Lae KIM, Suwon-si (KR); Taek Yong KIM, Suwon-si (KR); Tae Jin PARK, Suwon-si (KR)

(21) Appl. No.: 19/261,476

(22) Filed: Jul. 7, 2025

(30) Foreign Application Priority Data
Oct. 11, 2024 (KR) 10-2024-0138721

(51) Int. Cl. G11C 5/06; H01L 23/00; H10B 12/00

(52) U.S. Cl. CPC G11C 5/063; H10B 12/315; H10B 12/482; H10B 12/488; H10W 90/792

(57) ABSTRACT

A semiconductor memory device includes a cell region element isolation film disposed on a substrate and defining a cell array region, first and second active patterns disposed in the cell array region and alternately disposed along a first direction; a pad isolation pattern disposed on the cell region element isolation film and the first and second active patterns, a plurality of landing pads disposed in the pad isolation pattern and connected to the first and second active patterns, a plurality of pad block patterns disposed in the pad isolation pattern and disposed along a perimeter defined by the plurality of landing pads, and a plurality of data storage patterns disposed on the plurality of landing pads.

### CROSS-REFERENCE TO RELATED APPLICATION

This application claims priority under 35 U.S.C. 119 from Korean Patent Application No. 10-2024-0138721, filed on Oct. 11, 2024, in the Korean Intellectual Property Office, the contents of which are hereby incorporated by reference in their entirety.

### BACKGROUND

### 1. Technical Field

The present disclosure relates to a semiconductor memory device, and more particularly, to a semiconductor memory device including a vertical channel transistor (VCT) and a pad block pattern.

### 2. Discussion of Related Art

A semiconductor package may encapsulate an integrated circuit chip, making the chip suitable to be used in an electronic product. Research into increasing the performance, reliability, and integration density of semiconductor packages has been proposed to support the development of the electronics industry.

In the case of a two-dimensional (2D) or planar semiconductor memory device having planar channel transistors, the integration density is mainly determined by the area occupied by a unit cell, and the integration density is influenced by the level of fine pattern formation technology. However, the integration density of the 2D semiconductor memory device may be limited by its structure. Vertical channel transistors that are formed vertically on a semiconductor substrate have been proposed as a replacement for planar channel transistors and which may further improve device integration.

### SUMMARY

Aspects of the present disclosure provide a semiconductor memory device with an improved integration density and electrical characteristics.

Aspects of the present disclosure provide a semiconductor memory device in which an area where a pad block pattern faces a plurality of landing pads disposed above active patterns may be reduced.

Aspects of the present disclosure provide a semiconductor memory device in which an area for forming a bridge between outermost ones of landing pads and a pad block pattern may be reduced.

According to an aspect of the present disclosure, a semiconductor memory device includes a cell region element isolation film disposed on a substrate and defining a cell array region, a first active pattern and a second active pattern disposed in the cell array region and alternately disposed along a first direction; a pad isolation pattern disposed on the cell region element isolation film, the first active pattern and the second active pattern, a plurality of landing pads disposed in the pad isolation pattern and connected to the first active pattern and the second active pattern, a plurality of pad block patterns disposed in the pad isolation pattern and disposed along a perimeter defined by the plurality of landing pads, and a plurality of data storage patterns disposed on the plurality of landing pads.

According to an aspect of the present disclosure, a semiconductor memory device includes a cell region element isolation film disposed on a substrate and defining a cell array region, a plurality of active patterns disposed in the cell array region and disposed along a first direction and a second direction crossing the first direction, a pad isolation pattern disposed on the cell region element isolation film and the plurality of active patterns and comprising an inner pad isolation pattern and an outer pad isolation pattern, the outer pad isolation pattern surrounding the inner pad isolation pattern and being in contact with the inner pad isolation pattern, a plurality of landing pads disposed in the inner pad isolation pattern and respectively connected to the plurality of active patterns, a plurality of pad block patterns disposed in the pad isolation pattern, each of the plurality of pad block patterns being disposed in the outer pad isolation pattern, and a plurality of data storage patterns disposed on the plurality of landing pads.

According to an aspect of the present disclosure, a semiconductor memory device includes a plurality of bit lines disposed on a substrate and extending in a first direction, a cell region element isolation film disposed on the plurality of bit lines and defining a cell array region, a first back gate electrode and a second back gate electrode disposed in the cell array region on the substrate, arranged in the first direction, and extending in a second direction, a first word line and a second word line disposed between the first back gate electrode and the second back gate electrode adjacent in the first direction and extending in the second direction, a plurality of first active patterns disposed between the first back gate electrode and the first word line and arranged in the second direction; a plurality of second active patterns disposed between the second back gate electrode and the second word line and arranged in the second direction, a pad isolation pattern disposed on the cell region element isolation film, the plurality of first active patterns and the plurality of second active patterns, a plurality of landing pads disposed in the pad isolation pattern and respectively connected to the plurality of first active patterns and the plurality of second active patterns, a plurality of pad block patterns disposed in the pad isolation pattern and disposed along perimeters of the landing pads, and a plurality of data storage patterns disposed on the plurality of landing pads, wherein the pad block patterns comprise a plurality of first pad block patterns arranged along the first direction and a plurality of second pad block patterns arranged along the second direction.

According to an aspect of the present disclosure, a method for fabricating a semiconductor memory device according to some embodiments includes providing a first sub-substrate including a cell array region and a peripheral circuit region disposed around at least a portion of the cell array region, a cell region element isolation film disposed in the cell array region and the peripheral circuit region, wherein a plurality of back gate electrodes, a first word line and a second word line, a plurality of first active patterns and a plurality of second active patterns are disposed in the cell array region; forming a pad structure pattern on the cell array region including a contact structure pattern and a first sacrificial pad pattern, wherein the pad structure pattern includes a plurality of recesses exposing a first portion of the cell region element isolation film; forming an outer pad isolation pattern in the plurality of recesses and on a sidewall of the pad structure pattern in the cell array region and proximate to the peripheral circuit region; patterning the pad structure pattern to form a plurality of contact patterns on the plurality of first active patterns and the plurality of second active patterns and spaced apart from the outer pad isolation pattern, and a plurality of contact block patterns in the outer pad isolation pattern; forming an inner pad isolation pattern in the cell array region between the plurality of contact patterns; removing the first sacrificial pad pattern of the pad structure pattern to expose the plurality of contact patterns and the plurality of contact block patterns; forming a plurality of landing pads on the plurality of contact patterns and a plurality of first pad block patterns on the plurality of contact block patterns in the outer pad isolation pattern; and forming a plurality of data storage patterns on the landing pads.

According to some embodiments a method may further include bonding the plurality of data storage patterns to a second sub-substrate; removing the first sub-substrate; and forming a plurality of bit lines electrically connected to the plurality of first active patterns and the plurality of second active patterns.

According to some embodiments a method may further include forming a bit line contact plug on the bit lines; and forming a word line contact plug on the first and second word lines.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is a layout diagram illustrating a semiconductor memory device according to some embodiments.

FIG. 2 is a layout diagram of a boundary portion between a cell array region and a peripheral circuit region of FIG. 1.

FIG. 3 is a diagram illustrating the shape and positional relationship of landing pads, pad block patterns, and a pad isolation pattern around them of FIG. 2.

FIG. 4 is a cross-sectional view taken along lines A-A and B-B of FIG. 2.

FIG. 5 is a cross-sectional view taken along lines C-C and D-D of FIG. 2.

FIG. 6 is an enlarged view of part P of FIG. 4.

FIG. 7, FIG. 8, and FIG. 9 are enlarged views of part Q of FIG. 5.

FIG. 10 is a diagram illustrating a semiconductor memory device according to some embodiments.

FIG. 11, FIG. 12, and FIG. 13 are diagrams illustrating a semiconductor memory device according to some embodiments.

FIG. 14 and FIG. 15 are diagrams illustrating a semiconductor memory device according to some embodiments.

FIGS. 16 to 19 are diagrams each illustrating a semiconductor memory device according to some embodiments.

FIGS. 20 to 59 are views illustrating the intermediate steps for explaining a method for fabricating a semiconductor memory device according to some embodiments.

### DETAILED DESCRIPTION

Hereinafter, a semiconductor package and a method for manufacturing the semiconductor package according to some embodiments will be described referring to the accompanying drawings.

In a semiconductor memory device, a bridge between landing pads and a pad block pattern may be a defect that reduces reliability and/or performance. For example, in a case that a single pad block pattern is disposed around the landing pads, a bridge may occur between the outermost landing pads and the pad block pattern. In the semiconductor memory device according to some embodiments, an area where a pad block pattern faces the landing pads disposed above active patterns may be reduced, and an area for forming a bridge between outermost ones of landing pads and the pad block pattern may be reduced. For example, the pad block pattern may be disposed as a plurality of island shaped pad block patterns around an array of landing pads. The island pad block patterns may be disposed apart from each other, and apart from the landing pads. The island pad block patterns may be separated from each other by an outer pad isolation pattern, and may be separated from the landing pads by an inner pad isolation pattern.

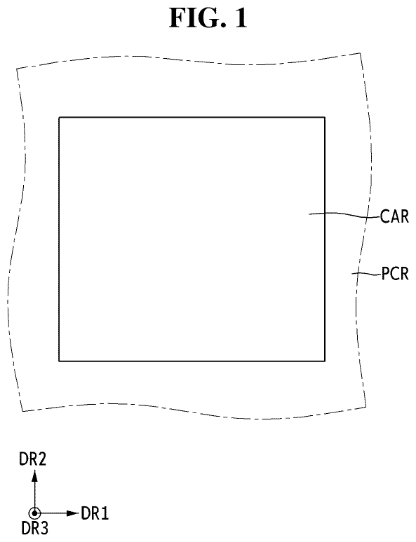

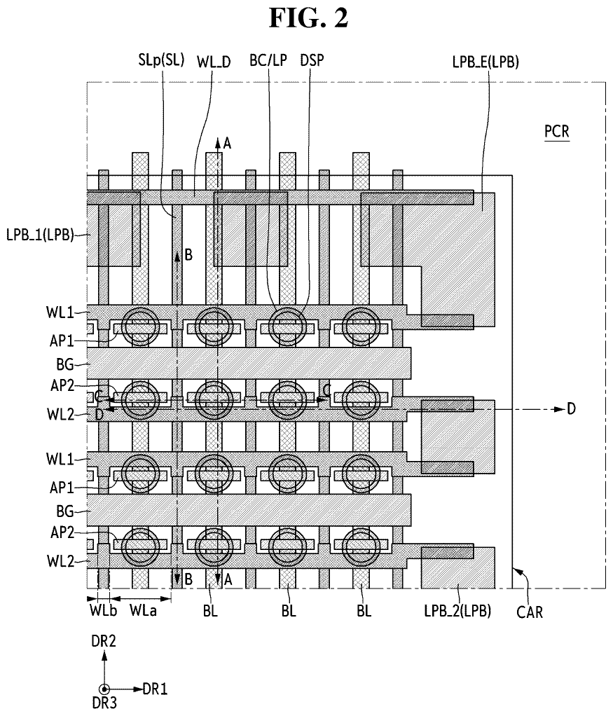

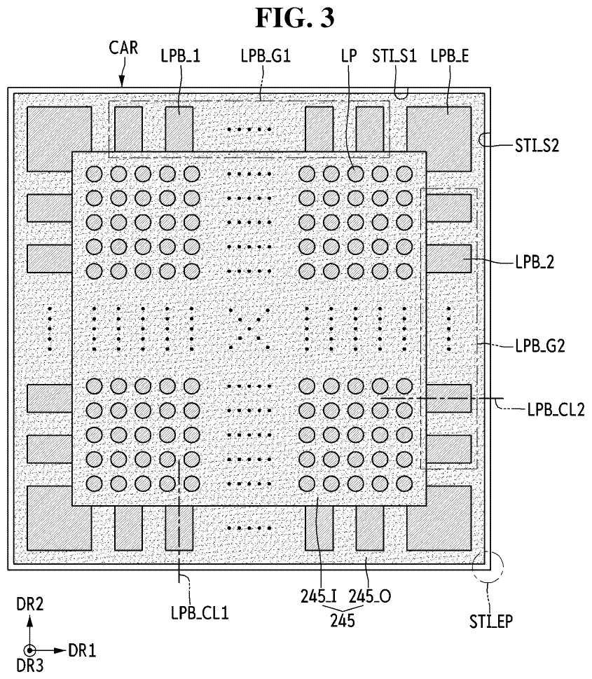

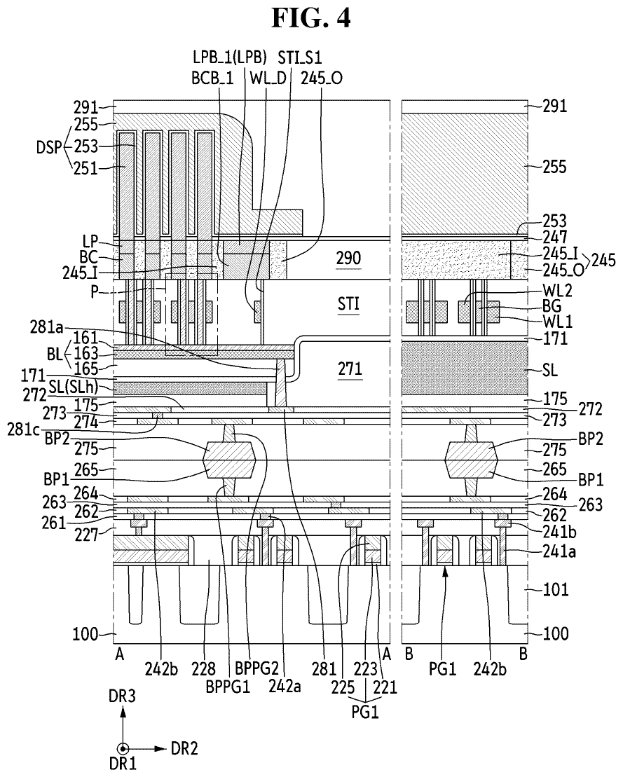

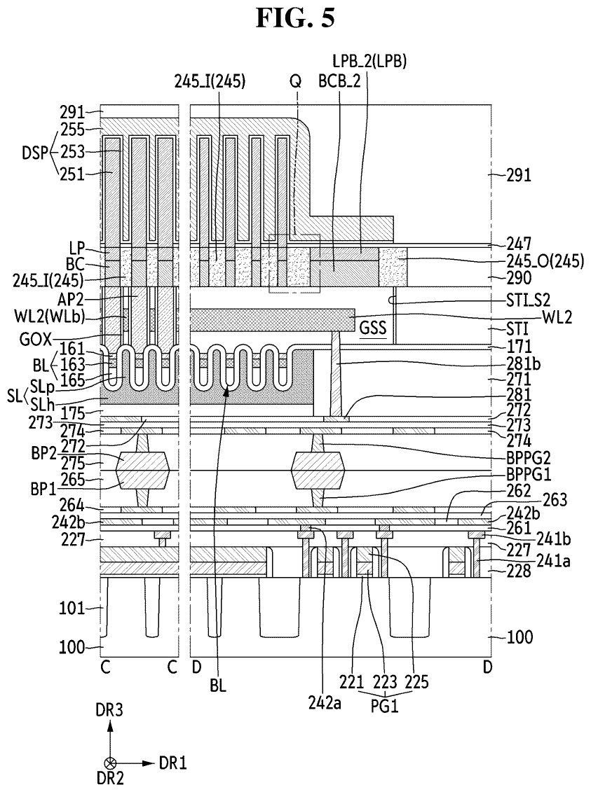

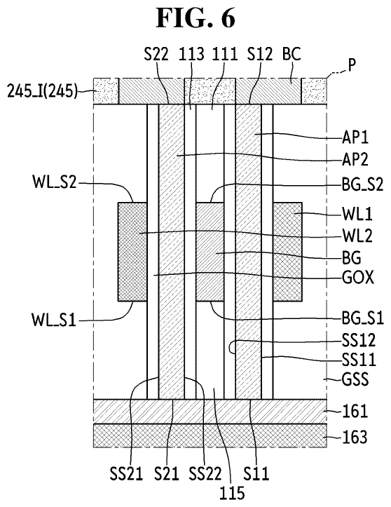

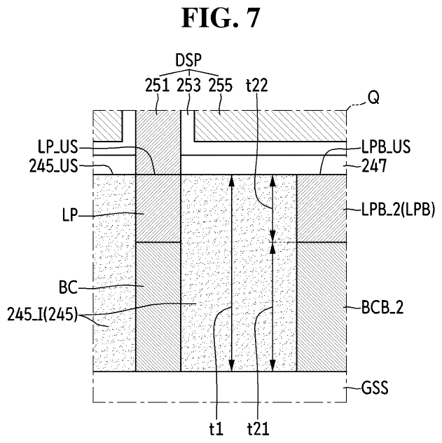

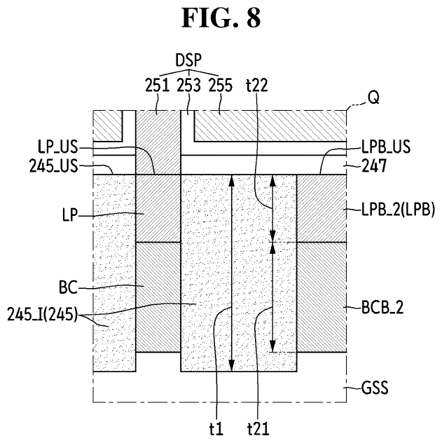

FIG. 1 is a layout diagram illustrating a semiconductor memory device according to some embodiments. FIG. 2 is a layout diagram of a boundary portion between a cell array region and a peripheral circuit region of FIG. 1. FIG. 3 is a diagram illustrating the shape and positional relationship of landing pads, pad block patterns, and a pad isolation pattern around them of FIG. 2. FIG. 4 is a cross-sectional view taken along lines A-A and B-B of FIG. 2. FIG. 5 is a cross-sectional view taken along lines C-C and D-D of FIG. 2. FIG. 6 is an enlarged view of part P of FIG. 4. Each of FIGS. 7 to 9 is an enlarged view of part Q of FIG. 5.

A semiconductor memory device according to embodiments of the present disclosure may include memory cells including a vertical channel transistor VCT.

Referring to FIGS. 1 to 9, a semiconductor memory device according to some embodiments may include bit lines BL, first word lines WL1, second word lines WL2, back gate electrodes BG, first active patterns AP1, second active patterns AP2, landing pads LP, a pad block pattern LPB, a pad isolation pattern 245, data storage patterns DSP, and a first peri-gate structure PG1.

A substrate 100 may be a silicon substrate, or may include other materials such as silicon germanium, indium antimonide, lead tellurium compound, indium arsenide, indium phosphide, gallium arsenide, or gallium antimonide, but is not limited thereto.

The substrate 100 may include a cell array region CAR and a peripheral circuit region PCR. The cell array region CAR may be a region where the data storage pattern DSP is disposed. The peripheral circuit region PCR may be defined around the cell array region CAR. A cell region element isolation film STI may be disposed on the peripheral circuit region PCR of the substrate 100. In plan view, the cell region element isolation film STI may define the cell array region CAR of the substrate 100.

A first element isolation film 101 may be disposed in the substrate 100. The first element isolation film 101 may define an active area in the substrate 100. The first element isolation film 101 includes an insulating material.

The first peri-gate structure PG1 may be disposed on the substrate 100. For example, the first peri-gate structure PG1 may be disposed on an upper surface of the substrate 100. The first peri-gate structure PG1 may be disposed in the cell array region CAR and the peripheral circuit region PCR. The first peri-gate structure PG1 may be disposed across the cell array region CAR and the peripheral circuit region PCR. In other words, a first part of the first peri-gate structure PG1 may be disposed in the cell array region CAR of the substrate 100, and a second part of the first peri-gate structure PG1 may be disposed in the peripheral circuit region PCR of the substrate 100.

The first peri-gate structure PG1 may be included in a sensing transistor, a transmission transistor, or a driving transistor. For example, the first peri-gate structure PG1 included in the sensing transistor may be disposed on the cell array region CAR of the substrate 100, but is not limited thereto. The type of a transistor of a peripheral circuit disposed on the cell array region CAR of the substrate 100 may vary depending on the design layout of the semiconductor memory device.

The first peri-gate structure PG1 may include a peri-gate insulating film 221, a first peri-lower conductive pattern 223, and a first peri-upper conductive pattern 225. For example, the peri-gate insulating film 221 may be disposed on the upper surface of the substrate 100, the first peri-lower conductive pattern 223 may be disposed on the peri-gate insulating film 221, and the first peri-upper conductive pattern 225 may be disposed on the first peri-lower conductive pattern 223. For example, the peri-gate insulating film 221, the first peri-lower conductive pattern 223, and the first peri-upper conductive pattern 225 may be disposed in a stack. The first peri-gate insulating film 221 may include silicon oxide, silicon oxynitride, or a high-k insulating material having a dielectric constant higher than silicon oxide, or a combination thereof. The high-k insulating material may include, for example, at least one of metal oxide, metal oxynitride, metal silicon oxide, or metal silicon oxynitride, but is not limited thereto.

Each of the first peri-lower conductive pattern 223 and the first peri-upper conductive pattern 225 may include a conductive material. For example, the first peri-lower conductive pattern 223 and the first peri-upper conductive pattern 225 may each include at least one of a doped semiconductor material, conductive metal nitride, conductive metal silicon nitride, metal carbonitride, conductive metal silicide, conductive metal oxide, conductive metal oxynitride, a two-dimensional (2D) material, or metal. Although the first peri-gate structure PG1 is illustrated as including a plurality of conductive patterns, it is not limited thereto. In the semiconductor memory device according to some embodiments, the 2D material may be a metallic material and/or a semiconductor material. The 2D material may include a 2D allotrope or a 2D compound. For example, the 2D material may include at least one of graphene, molybdenum disulfide (MoS₂), molybdenum diselenide (MoSe₂), tungsten diselenide (WSe₂), or tungsten disulfide (WS₂), but is not limited thereto. That is, the 2D materials described herein are merely examples, and the 2D materials that may be included in the semiconductor memory device of the present disclosure are not limited thereto.

The first peri-gate structure PG1 may further include a first peri-gate mask pattern disposed on the first peri-upper conductive pattern 225. The first peri-gate mask pattern may be made of an insulating material.

In the semiconductor memory device according to some embodiments, the first peri-gate structure PG1 may be disposed between the bit lines BL and the substrate 100. For example, the first peri-gate structure PG1 may be disposed on the substrate 100 and the bit lines BL may be disposed at a level of the semiconductor memory device above a level of the first peri-gate structure PG1.

A first peri-lower insulating film 227 and a second peri-lower insulating film 228 may be disposed on the upper surface of the substrate 100. The first peri-lower insulating film 227 and the second peri-lower insulating film 228 may each include an insulating material.

A first peri-contact plug 241a and a first peri-wiring line 241b may be disposed in the first peri-lower insulating film 227 and the second peri-lower insulating film 228. For example, the first peri-contact plug 241a may penetrate the second peri-lower insulating film 228 and a portion of the first peri-lower insulating film 227, and a first peri-wiring line 241b may penetrate a portion of the first peri-lower insulating film 227 to be disposed on the first peri-contact plug 241a. The first peri-contact plug 241a and the first peri-wiring line 241b may be connected to a first source/drain region disposed on at least one side of the first peri-gate structure PG1. The first peri-contact plug 241a and the first peri-wiring line 241b may be connected to the conductive patterns 223 and 225 of the first peri-gate structure PG1. For example, the first peri-wiring line 241b may be a wiring line closest to the first peri-gate structure PG1 in a third direction DR3.

Although the first peri-contact plug 241a and the first peri-wiring line 241b are shown as different films, they are not limited thereto. A boundary between the first peri-contact plug 241a and the first peri-wiring line 241b may not be distinguished or may be omitted. Each of the first peri-contact plug 241a and the first peri-wiring line 241b may include a conductive material.

A first peri-upper insulating film 261, a second peri-upper insulating film 262, a third peri-upper insulating film 263, and a fourth peri-upper insulating film 264 may be disposed on the first peri-contact plug 241a and the first peri-wiring line 241b. For example, the first peri-upper insulating film 261, the second peri-upper insulating film 262, the third peri-upper insulating film 263, and the fourth peri-upper insulating film 264 may be stacked in the third direction DR3. Each of the first to fourth peri-upper insulating films 261, 262, 263, and 264 may include an insulating material. In an example, an insulating film formed of a single film may be disposed on the first peri-contact plug 241a and the first peri-wiring line 241b. For example, an insulating film may be formed on side surfaces of the first peri-contact plug 241a and the first peri-wiring line 241b.

A first peri-connection structure may include a first peri-connection via 242a and a first peri-connection line 242b. The first peri-connection structure may be connected to the first peri-wiring line 241b. Each of the first peri-connection via 242a and the first peri-connection line 242b may include a conductive material.

Although the first peri-connection via 242a and the first peri-connection line 242b are shown as different films, they are not limited thereto. The first peri-connection structure is shown as including a plurality of first peri-connection lines 242b disposed at two different metal levels, but this is merely for simplicity of description, and the present disclosure is not limited thereto. For example, the plurality of first peri-connection lines 242b may be disposed at more than two metal levels. In an example, the first peri-connection line 242b disposed at one metal level.

A fifth peri-upper insulating film 265 may be disposed on the first peri-connection structure including the first peri-connection via 242a and the first peri-connection line 242b. The fifth peri-upper insulating film 265 may include an insulating material.

A lower bonding pad BP1 may be disposed above the first peri-gate structure PG1. The lower bonding pad BP1 may be connected to the first peri-connection structure including the first peri-connection via 242a and the first peri-connection line 242b.

For example, at least one of the lower bonding pads BP1 may be connected to the first peri-gate structure PG1. At least another one of the lower bonding pads BP1 may be connected to the first source/drain region disposed on at least one side of the first peri-gate structure PG1.

A lower pad plug BPPG1 may electrically connect the lower bonding pad BP1 to the first peri-connection line 242b. The lower bonding pad BP1 and the lower pad plug BPPG1 may be disposed in the fifth peri-upper insulating film 265. For example, the lower bonding pad BP1 and the lower pad plug BPPG1 may penetrate the fifth peri-upper insulating film 265.

A first cell interlayer insulating film 271, a second cell interlayer insulating film 272, a third cell interlayer insulating film 273, a fourth cell interlayer insulating film 274, and a fifth cell interlayer insulating film 275 may be disposed on the fifth peri-upper insulating film 265. For example, the fifth cell interlayer insulating film 275, the fourth cell interlayer insulating film 274, the third cell interlayer insulating film 273, the second cell interlayer insulating film 272, and the first cell interlayer insulating film 271 may be stacked in the third direction DR3. The first cell interlayer insulating film 271, the second cell interlayer insulating film 272, the third cell interlayer insulating film 273, the fourth cell interlayer insulating film 274, and the fifth cell interlayer insulating film 275 may be disposed on the lower bonding pad BP1 and the fifth peri-upper insulating film 265.

Each of the first to fifth cell interlayer insulating films 271, 272, 273, 274, and 275 may include an insulating material.

An upper bonding pad BP2 may be disposed on the lower bonding pad BP1. The upper bonding pad BP2 may be disposed in the fifth cell interlayer insulating film 275.

The upper bonding pad BP2 may be connected to the lower bonding pad BP1. The upper bonding pad BP2 may be in contact with the lower bonding pad BP1.

First cell connection lines 281 may be disposed at a level above the upper bonding pad BP2. The first cell connection lines 281 may be disposed at a level between the upper bonding pad BP2 and the bit line BL. The first cell connection lines 281 may be connected to at least one of the bit lines BL, a shielding conductive pattern SL, the first word lines WL1, or the second word lines WL2, as described herein.

Although it is illustrated that the plurality of first cell connection lines 281 disposed at different metal levels are disposed between the upper bonding pad BP2 and the bit line BL, this is merely for simplicity of description and the present disclosure is not limited thereto. The first cell connection line 281 disposed at a single metal level may be disposed between the upper bonding pad BP2 and the bit line BL.

An upper pad plug BPPG2 may connect the upper bonding pad BP2 to the first cell connection line 281. The upper bonding pad BP2 may be electrically connected to the first cell connection line 281 through the upper pad plug BPPG2.

The upper bonding pad BP2 and the upper pad plug BPPG2 may be disposed in the fifth cell interlayer insulating film 275. For example, the upper bonding pad BP2 and the upper pad plug BPPG2 may penetrate the fifth cell interlayer insulating film 275. The first cell connection lines 281 may be disposed in the second cell interlayer insulating film 272 and the fourth cell interlayer insulating film 274. In the third cell interlayer insulating film 273, a cell connection via 281c that connects the first cell connection lines 281 at different metal levels may be disposed.

The upper pad plug BPPG2 and the lower pad plug BPPG1 may include a conductive material containing metal. Each of the lower bonding pad BP1 and the upper bonding pad BP2 may include a conductive material including metal. The first cell connection line 281 may include a conductive material containing metal.

Although it is illustrated that each of the lower bonding pad BP1 and the upper bonding pad BP2 is a single film, this is merely for simplicity of description, and the present disclosure is not limited thereto. The upper pad plug BPPG2 and the lower pad plug BPPG1 are shown as single films, but they are not limited thereto. The first cell connection line 281 is shown as a single film, but it is not limited thereto.

A bonding insulating film may be disposed between the fifth cell interlayer insulating film 275 and the fifth peri-upper insulating film 265. The bonding insulating film may be disposed extending along an interface between the lower bonding pad BP1 and the upper bonding pad BP2. The interface between the lower bonding pad BP1 and the upper bonding pad BP2 may be a boundary between the lower bonding pad BP1 and the upper bonding pad BP2. In one example, the bonding insulating film may include silicon carbonitride. In another example, the bonding insulating film may include silicon oxide.

At the interface between the lower bonding pad BP1 and the upper bonding pad BP2, the width of the lower bonding pad BP1 may be the same as the width of the upper bonding pad BP2. In an example, at the interface between the lower bonding pad BP1 and the upper bonding pad BP2, the width of the lower bonding pad BP1 may be different from the width of the upper bonding pad BP2.

At the interface between the lower bonding pad BP1 and the upper bonding pad BP2, the lower bonding pad BP1 may be aligned with the upper bonding pad BP2. In an example, at the interface between the lower bonding pad BP1 and the upper bonding pad BP2, the lower bonding pad BP1 may be misaligned with the upper bonding pad BP2.

A shielding structure may be disposed above the substrate 100. The shielding structure may include the shielding conductive pattern SL and a shielding insulating liner 171 and a shielding insulating capping film 175. For example, the shielding structure may be disposed on the first cell connection line 281. The first cell connection lines 281 may be disposed between the shielding structure and the upper bonding pad BP2.

The shielding insulating liner 171 and the shielding insulating capping film 175 may be shielding insulating films.

The shielding conductive pattern SL may include a shielding conductive plate SLh, and a plurality of shielding conductive line patterns SLp. The shielding conductive plate SLh may have a shape of a flat plate in the first direction DR1 and the second direction DR2. The shielding conductive plate SLh may be disposed on the cell array region CAR. A part of the shielding conductive plate SLh may extend to the peripheral circuit region PCR.

Each of the shielding conductive line patterns SLp may extend in a second direction DR2. The shielding conductive line patterns SLp may be adjacent in a first direction DR1.

The shielding conductive line pattern SLp may protrude from the shielding conductive plate SLh in the third direction DR3. Each of the shielding conductive line patterns SLp may protrude toward the first and second word lines WL1 and WL2. The shielding conductive line pattern SLp may be directly connected to the shielding conductive plate SLh.

For example, the first direction DR1 and the second direction DR2 may be horizontal directions that are parallel to the substrate 100 and that cross each other. For example, the second direction DR2 may be perpendicular to the first direction DR1. The third direction DR3 may be a vertical direction perpendicular to the substrate 100.

The shielding conductive pattern SL includes a conductive material. The shielding conductive pattern SL may include, for example, at least one of conductive metal nitride, conductive metal silicon nitride, metal carbonitride, conductive metal silicide, conductive metal oxide, conductive metal oxynitride, a 2D material, or metal.

The shielding insulating capping film 175 may be disposed on the second cell interlayer insulating film 272. The shielding insulating capping film 175 may be disposed between the second cell interlayer insulating film 272 and the shielding conductive pattern SL.

The shielding insulating capping film 175 may be in contact with the shielding conductive pattern SL. For example, the shielding insulating capping film 175 may be in contact with a lower surface of the shielding conductive plate SLh.

The shielding insulating liner 171 may be disposed on the shielding conductive pattern SL. The shielding insulating liner 171 may be disposed between the bit line BL and the shielding conductive pattern SL. The shielding insulating liner 171 may extend along the profile of the shielding conductive plate SLh and the shielding conductive line patterns SLp. The shielding insulating liner 171 may not extend along a sidewall of the shielding conductive pattern SL. The sidewall of the shielding conductive pattern SL may define a boundary of the shielding conductive pattern SL. For example, the sidewall of the shielding conductive pattern SL may be disposed in contact with a sidewall of the first cell interlayer insulating film 271. The shielding conductive pattern SL may be disposed between the shielding insulating liner 171 and the shielding insulating capping film 175.

A part of the shielding insulating liner 171 may extend along the upper surface of the first cell interlayer insulating film 271. The first cell interlayer insulating film 271 may cover the sidewall of the shielding insulating capping film 175 and the sidewall of the shielding conductive pattern SL.

Each of the shielding insulating liner 171 and the shielding insulating capping film 175 may be made of an insulating material. When the shielding insulating liner 171 and the shielding insulating capping film 175 include the same material, a boundary between the shielding insulating liner 171 and the shielding insulating capping film 175 may not be apparent.

In a case that the shielding structure is disposed between the bit lines BL adjacent in the first direction DR1, coupling noise between the bit lines BL may be reduced.

In an example, the semiconductor memory device according to some embodiments may not include the shielding conductive pattern SL. For example, the shielding conductive pattern SL may be omitted.

The bit lines BL may be disposed on the substrate 100. The bit line BL may be elongated in the second direction DR2. Adjacent bit lines BL may be spaced apart from each other in the first direction DR1. The bit line BL includes a long sidewall extending in the second direction DR2 and a short sidewall extending in the first direction DR1.

The bit lines BL may be disposed above the shielding conductive pattern SL. The bit lines BL may be disposed above the shielding conductive plate SLh.

The bit line BL may be disposed adjacent to the shielding conductive line pattern SLp. The bit line BL may be disposed adjacent to the shielding conductive line pattern SLp in the first direction DR1. In other words, the shielding conductive line pattern SLp may extend in the second direction DR2 along the long sidewall of the bit line BL.

Each bit line BL may be disposed between the shielding conductive line patterns SLp adjacent in the first direction DR1. The bit line BL may be disposed on the shielding insulating liner 171 between the shielding conductive line patterns SLp adjacent in the first direction DR1. For example, the shielding insulating liner 171 may be in contact with the bit line BL.

Each bit line BL may extend from the cell array region CAR to the peripheral circuit region PCR. The end portion of each bit line BL may be disposed on the peripheral circuit region PCR. A part of the bit line BL may overlap the cell region element isolation film STI surrounding the cell array region CAR in the third direction DR3.

In one example, at least one bit line BL disposed along the boundary between the cell array region CAR and the peripheral circuit region PCR may be a dummy bit line that is not used in a cell array operation. In another example, no dummy bit line may be disposed along the boundary between the cell array region CAR and the peripheral circuit region PCR.

Each of the bit lines BL may include a semiconductor pattern 161, a metal pattern 163, and a bit line mask pattern 165 that are sequentially stacked. For example, the bit line mask pattern 165 may be disposed on the shielding insulating liner 171, the metal pattern 163 may be disposed on the bit line mask pattern 165, and the semiconductor pattern 161 may be disposed on the metal pattern 163. In an example, the bit line BL may include one of the semiconductor pattern 161 and the metal pattern 163. As another example, the bit line BL may not include the bit line mask pattern 165. For example, the bit line mask pattern 165 may be omitted.

The bit line BL may include a conductive bit line. The conductive bit line may include a film made of a conductive material in the bit line BL. The conductive bit line may include the semiconductor pattern 161 and the metal pattern 163.

The semiconductor pattern 161 may include a conductive semiconductor material. The conductive semiconductor material may be, for example, a semiconductor material doped with impurities. The semiconductor pattern 161 may include at least one of polysilicon, polysilicon germanium, polygermanium, amorphous silicon, amorphous silicon germanium, or amorphous germanium.

The metal pattern 163 may include a conductive material including metal. The metal pattern 163 may include, for example, at least one of conductive metal nitride, conductive metal silicon nitride, metal carbonitride, conductive metal silicide, conductive metal oxide, conductive metal oxynitride, a 2D material, or metal.

The bit line mask pattern 165 may include an insulating material. The bit line mask pattern 165 may include silicon nitride or silicon oxynitride, but is not limited thereto.

The cell region element isolation film STI may be disposed above the substrate 100. The cell region element isolation film STI may be spatially separated from the upper surface of the substrate 100. For example, the cell region element isolation film STI may be disposed on the first cell interlayer insulating film 271, the bit lines BL, and the shielding conductive pattern SL. The shielding insulating liner 171 may be disposed between the cell region element isolation film STI and the first cell interlayer insulating film 271 in the third direction DR3.

The cell region element isolation film STI may include a first cell region sidewall STI_S1 and a second cell region sidewall STI_S2. The cell region element isolation film STI may include a cell region corner STI_EP where the first cell region sidewall STI_S1 and the second cell region sidewall STI_S2 meet. The first cell region sidewall STI_S1 may extend in the first direction DR1. The second cell region sidewall STI_S2 may extend in the second direction DR2.

In plan view, the cell region element isolation film STI may define the cell array region CAR. The first and second word lines WL1 and WL2, the back gate electrodes BG, and the first and second active patterns AP1 and AP2 may be disposed in the cell array region CAR. Although it is illustrated that the cell region element isolation film STI is a single film, the present disclosure is not limited thereto. For example, the cell region element isolation film STI may include two or more films. The cell region element isolation film STI may include an insulating material.

The first active patterns AP1 and the second active patterns AP2 may be disposed on each bit line BL. The first active patterns AP1 and the second active patterns AP2 may be disposed between the bit lines BL and the data storage patterns DSP. The first active patterns AP1 and the second active patterns AP2 may be alternately disposed along the second direction DR2.

The first active patterns AP1 may be spaced apart from each other in the first direction DR1. The first active patterns AP1 may be spaced apart from each other at regular intervals. The second active patterns AP2 may be spaced apart from each other in the first direction DR1. The second active patterns AP2 may be spaced apart from each other at regular intervals. The first active pattern AP1 may be spaced apart from the second active pattern AP2 in the second direction DR2. The first active patterns AP1 and the second active patterns AP2 may be two-dimensionally arranged along the first and second directions DR1 and DR2 that intersect each other.

For example, each of the first active pattern AP1 and the second active pattern AP2 may be made of a monocrystalline semiconductor material. In one example, each of the first active pattern AP1 and the second active pattern AP2 may be made of monocrystalline silicon. Each of the first active pattern AP1 and the second active pattern AP2 may be a silicon active pattern.

Each of the first active pattern AP1 and the second active pattern AP2 may have a length in the first direction DR1, a width in the second direction DR2, and a height in the third direction DR3. Each of the first active pattern AP1 and the second active pattern AP2 may have a substantially uniform width.

The width of the first active pattern AP1 and the width of the second active pattern AP2 may be within a range of a few nanometers (nm) to tens of nm. For example, the width of the first active pattern AP1 and the width of the second active pattern AP2 may be about 1 nm to about 30 nm, more preferably about 1 nm to about 10 nm, but is not limited thereto. The length of each of the first and second active patterns AP1 and AP2 may be greater than the line width of the bit line BL. That is, the length of each of the first and second active patterns AP1 and AP2 may be greater than the width of the bit line BL in the first direction DR1. The terms “about” or “approximately” as used herein are inclusive of the stated value(s) and mean within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In FIG. 4 and FIG. 6, the first active pattern AP1 may include a first surface S11 and a second surface S12, which are disposed opposite to each other in the third direction DR3. The second active pattern AP2 may include a first surface S21 and a second surface S22, which are disposed opposite to each other in the third direction DR3.

The first surface S11 of the first active pattern and the first surface S21 of the second active pattern may face the bit line BL. The first surface S11 of the first active pattern and the first surface S21 of the second active pattern are connected to the bit line BL. For example, the first surface S11 of the first active pattern and the first surface S21 of the second active pattern may be connected to the semiconductor pattern 161 of the bit line BL. In an example, if the semiconductor pattern 161 is omitted, the first surface S11 of the first active pattern and the first surface S21 of the second active pattern may be connected to the metal pattern 163.

The second surface S12 of the first active pattern and the second surface S22 of the second active pattern may face the landing pad LP. The second surface S12 of the first active pattern and the second surface S22 of the second active pattern may be connected to the landing pads LP. The second surface S12 of the first active pattern and the second surface S22 of the second active pattern may each be connected to the data storage pattern DSP.

The first active pattern AP1 may include a first sidewall SS11 and a second sidewall SS12, which may be disposed opposite to each other in the second direction DR2. The second active pattern AP2 may include a first sidewall SS21 and a second sidewall SS22, which may be disposed opposite to each other in the second direction DR2. The second sidewall SS12 of the first active pattern may face the second sidewall SS22 of the second active pattern.

The first sidewall SS11 of the first active pattern may be adjacent to the first word line WL1. The first sidewall SS21 of the second active pattern may be adjacent to the second word line WL2.

In one example, each of the first active pattern AP1 and the second active pattern AP2 may include a first dopant region adjacent to the bit line BL and a second dopant region adjacent to the contact pattern BC. Each of the first active pattern AP1 and the second active pattern AP2 may include a channel region between the first dopant region and the second dopant region. The first dopant region and the second dopant region may be regions formed by doping dopants into the first active pattern AP1 and the second active pattern AP2. In an example, one or both of the first active pattern AP1 or the second active pattern AP2 may omitted a dopant region. For example, one or both of the first active pattern AP1 or the second active pattern AP2 may omit the first dopant region or the second dopant region.

During the operation of the semiconductor memory device, the channel regions of the first and second active patterns AP1 and AP2 may be controlled by the first and second word lines WL1 and WL2 and the back gate electrodes BG. In the case that the first and second active patterns AP1 and AP2 are made of a monocrystalline semiconductor material, the leakage current characteristics of the semiconductor memory device may be improved.

The back gate electrodes BG may be disposed above the bit line BL and the shielding conductive pattern SL. The back gate electrodes BG may be spaced apart from each other in the second direction DR2. The back gate electrodes BG may be spaced apart from each other at regular intervals. Each of the back gate electrodes BG may extend in the first direction DR1 across the bit line BL.

Each of the back gate electrodes BG may be disposed between the first active pattern AP1 and the second active pattern AP2 adjacent to each other in the second direction DR2. The first active pattern AP1 and the second active pattern AP2 may be spaced apart from each other in the second direction DR2 with the back gate electrode BG disposed therebetween. Each of the back gate electrodes BG may be disposed between the second sidewall SS12 of the first active pattern and the second sidewall SS22 of the second active pattern. In other words, the first active pattern AP1 may be disposed on a first side of each of the back gate electrodes BG, and the second active pattern AP2 may be disposed on a second side of each of the back gate electrodes BG. The height of the back gate electrode BG in the third direction DR3 may be less than the heights of the first and second active patterns AP1 and AP2.

The first active pattern AP1 may be disposed between the first word line WL1 and the back gate electrode BG. The second active pattern AP2 may be disposed between the second word line WL2 and the back gate electrode BG. A pair of the first word line WL1 and the second word line WL2 may be disposed between the back gate electrodes BG adjacent in the second direction DR2.

The back gate electrode BG may include a first surface BG_S1 and a second surface BG_S2 opposite to each other in the third direction DR3. The first surface BG_S1 of the back gate electrode is closer to the bit line BL than the second surface BG_S2 of the back gate electrode. The first surface BG_S1 of the back gate electrode may face the bit line BL.

The back gate electrode BG may include a conductive material, and may include, for example, at least one of a conductive semiconductor material, conductive metal nitride, conductive metal silicon nitride, metal carbonitride, conductive metal silicide, conductive metal oxide, conductive metal oxynitride, a 2D material, or metal. Although the back gate electrode BG is depicted as a single film, it is merely for simplicity of description and the present disclosure is not limited thereto. For example, the back gate electrode BG may include two or more films.

During the operation of the semiconductor memory device, a voltage may be applied to the back gate electrode BG to adjust the threshold voltage of a vertical channel transistor. By adjusting the threshold voltage of the vertical channel transistor, the deterioration of the leakage current characteristics may be inhibited or prevented.

A back gate isolation pattern 111 may be disposed between the first active pattern AP1 and the second active pattern AP2 adjacent in the second direction DR2. The back gate isolation pattern 111 may extend in the first direction DR1 to be disposed side by side with the back gate electrode BG. The back gate isolation pattern 111 may be disposed on the second surface BG_S2 of the back gate electrode.

The back gate isolation pattern 111 may be made of an insulating material. The back gate isolation pattern 111 may include, for example, silicon oxide, silicon oxynitride, or silicon nitride, but is not limited thereto.

A back gate insulating pattern 113 may be disposed between the back gate electrode BG and the first active pattern AP1, and between the back gate electrode BG and the second active pattern AP2. The back gate insulating pattern 113 may be disposed between the back gate isolation pattern 111 and the first active pattern AP1, and between the back gate isolation pattern 111 and the second active pattern AP2.

The back gate insulating pattern 113 may extend along the second sidewall SS12 of the first active pattern and the second sidewall SS22 of the second active pattern. For example, the height of the back gate insulating pattern 113 may be the same as the heights the second sidewall SS12 of the first active pattern AP1 and the second sidewall SS22 of the second active pattern AP2. In the semiconductor memory device according to some embodiments, the back gate insulating pattern 113 may not extend along first surfaces WL_S1 of the first and second word lines WL1 and WL2.

The back gate insulating pattern 113 may be made of an insulating material. The back gate insulating pattern 113 may include, for example, silicon oxide, silicon oxynitride, or a high-k insulating material having a higher dielectric constant than silicon oxide, or a combination thereof.

The back gate capping pattern 115 may be disposed between the bit line BL and the back gate electrode BG. The back gate capping pattern 115 may be disposed between the first active pattern AP1 and the second active pattern AP2 adjacent in the second direction DR2. The back gate capping pattern 115 may extend in the first direction DR1 to be disposed side by side with the back gate electrode BG. The back gate capping pattern 115 may be disposed on the first surface BG_S1 of the back gate electrode. The thickness of the back gate capping pattern 115 between the bit lines BL may be different from the thickness of the back gate capping pattern 115 on the bit line BL, but the present disclosure is not limited thereto.

The back gate capping pattern 115 may be made of an insulating material. The back gate capping pattern 115 may include, for example, at least one of silicon oxide, silicon oxynitride, or silicon nitride, but is not limited thereto.

The first word line WL1 and the second word line WL2 may be disposed above the bit line BL and the shielding conductive pattern SL. Each of the first word line WL1 and the second word line WL2 may extend in the first direction DR1. The first word line WL1 and the second word line WL2 may be alternately arranged in the second direction DR2.

The first word line WL1 may be disposed on the first sidewall SS11 of the first active pattern. The second word line WL2 may be disposed on the first sidewall SS21 of the second active pattern. The first and second word lines WL1 and WL2 may be spaced apart from the back gate electrode BG in the second direction DR2. For example, the back gate electrode BG may be disposed between the first and second word lines WL1 and WL2 in the second direction DR2.

In the semiconductor memory device according to some embodiments, the first word line WL1 may not be disposed on the second sidewall SS12 of the first active pattern. The second word line WL2 may not be disposed on the second sidewall SS22 of the second active pattern.

The first active patterns AP1 and the second active patterns AP2 may be disposed between the first word line WL1 and the second word line WL2 that are adjacent in the second direction DR2. For example, the first active patterns AP1 may be disposed proximate to the first word line WL1 and on a first side of the first word line WL1, and the second active patterns AP2 may be disposed proximate to the second word line WL2 and on a second side of the second word line WL2 facing the first side of the first word line WL1. In other words, the first word line WL1 and the second word line WL2 may be disposed alternately with the first active patterns AP1 and the second active patterns AP2 that are adjacent in the second direction DR2.

In the semiconductor memory device according to some embodiments, the first word line WL1 and the second word line WL2 may be spaced apart from the bit lines BL and the data storage patterns DSP in the third direction DR3. For example, the first word line WL1 and the second word line WL2 may be located between the bit lines BL and the landing pads LP.

Each of the first word line WL1 and the second word line WL2 may have a width in the second direction DR2. For example, the width of the first word line WL1 and the width of the second word line WL2 above the bit line BL may be different from the width of the first word line WL1 and the width of the second word line WL2 above the shielding conductive pattern SL.

For example, each of the first word line WL1 and the second word line WL2 may include a first portion WLa of the word line and a second portion WLb of the word line. The width of the first portion WLa of the word line in the second direction DR2 may be smaller than the width of the second portion WLb of the word line in the second direction DR2. As an example, the first portion WLa of the word line may be disposed on the bit line BL. The second portion WLb of the word line may be disposed on the shielding conductive pattern SL. The second portion WLb of the word line may be disposed on the shielding conductive line pattern SLp.

Each of the first word line WL1 and the second word line WL2 may include the first portion WLa of the word line and the second portion WLb of the word line that are alternately disposed along the first direction DR1. In the first word line WL1, each of the first active patterns AP1 may be disposed between the second portions WLb of the word lines adjacent in the first direction DR1. In the second word line WL2, each of the second active patterns AP2 may be disposed between the second portions WLb of the word lines adjacent in the first direction DR1.

In an example, the width of the first portion WLa of the word line in the second direction DR2 may be the same as the width of the second portion WLb of the word line in the second direction DR2. In other words, the width of the first word line WL1 and the width of the second word line WL2 above the bit line BL may be the same as the width of the first word line WL1 and the width of the second word line WL2 above the shielding conductive pattern SL. In this case, a gate insulating pattern GOX, described herein, may be disposed in a space between the first active patterns AP1 adjacent in the first direction DR1, and a space between the second active patterns AP2 adjacent in the first direction DR1. For example, the gate insulating pattern GOX may fill the space between the first active patterns AP1 adjacent in the first direction DR1, and the space between the second active patterns AP2 adjacent in the first direction DR1.

The first word line WL1 and the second word line WL2 may include a first surface WL_S1 and a second surface WL_S2 opposite to each other in the third direction DR3. The first surfaces WL_S1 of the first and second word lines WL1 and WL2 may be closer to the bit line BL than the second surfaces WL_S2 of the first and second word lines WL1 and WL2. The first surfaces WL_S1 of the first and second word lines WL1 and WL2 face the bit line BL.

The first word line WL1 will be described as an example. In one example, the height of the first word line WL1 in the third direction DR3 may be the same as the height of the back gate electrode BG in the third direction DR3. In another example, the height of the first word line WL1 in the third direction DR3 may be greater than the height of the back gate electrode BG in the third direction DR3. In still another example, the height of the first word line WL1 in the third direction DR3 may be less than the height of the back gate electrode BG in the third direction DR3.

Further, in one example, with respect to the upper surface of the bit line BL, the height of the first surface WL_S1 of the first word line may be the same as the height of the first surface BG_S1 of the back gate electrode. In another example, the first surface WL_S1 of the first word line may be higher than the first surface BG_S1 of the back gate electrode. In still another example, the first surface WL_S1 of the first word line may be lower than the first surface BG_S1 of the back gate electrode. For example, the semiconductor pattern 161 may include the upper surface of the bit line BL. When the bit line BL does not include the semiconductor pattern 161, the metal pattern 163 may include the upper surface of the bit line BL.

In addition, in one example, with respect to the upper surface of the bit line BL, the height of the second surface WL_S2 of the first word line may be the same as the height of the second surface BG_S2 of the back gate electrode. In another example, the second surface WL_S2 of the first word line may be higher than the second surface BG_S2 of the back gate electrode. In still another example, the second surface WL_S2 of the first word line may be lower than the second surface BG_S2 of the back gate electrode.

The first word line WL1 and the second word line WL2 may include a conductive material. The first word line WL1 and the second word line WL2 may include, for example, at least one of a conductive semiconductor material, conductive metal nitride, conductive metal silicon nitride, metal carbonitride, conductive metal silicide, conductive metal oxynitride, a 2D material, or metal. Although the first word line WL1 and the second word line WL2 are each illustrated as a single film, this is merely for simplicity of description and the present disclosure is not limited thereto.

The first surfaces WL_S1 of the first and second word lines WL1 and WL2 may be flat. In an example, in one example, the first surfaces WL_S1 of the first and second word lines WL1 and WL2 may be concavely rounded. In another example, each of the first word line WL1 and the second word line WL2 may have a spacer shape. In other words, the first surfaces WL_S1 of the first and second word lines WL1 and WL2 may be convexly rounded.

The second surfaces WL_S2 of the first and second word lines WL1 and WL2 may be flat. In an example, the second surfaces WL_S2 of the first and second word lines WL1 and WL2 may be concave curved surfaces. Although it is illustrated that the first surface BG_S1 of the back gate electrode and the second surface BG_S2 of the back gate electrode are flat, the present disclosure is not limited thereto.

A dummy word line WL_D may extend along the boundary of the cell array region CAR. In the semiconductor memory device according to some embodiments, the dummy word line WL_D may extend in the first direction DR1. The dummy word line WL_D may not extend in the second direction DR2. The dummy word line WL_D may extend along the first cell region sidewall STI_S1 of the cell region element isolation film STI. The dummy word line WL_D may not extend along the second cell region sidewall STI_S2 of the cell region element isolation film STI. The dummy word line WL_D may be spaced apart from the first and second word lines WL1 and WL2 in the second direction DR2.

Gate insulating patterns GOX may be disposed between the first word line WL1 and the first active pattern AP1, and between the second word line WL2 and the second active pattern AP2. The gate insulating patterns GOX may extend in the first direction DR1 to be disposed side by side with the first word line WL1 and the second word line WL2.

The gate insulating pattern GOX may include, for example, silicon oxide, silicon oxynitride, a high-k insulating material having a higher dielectric constant than silicon oxide, or a combination thereof. The high-k insulating film may include, for example, at least one of metal oxide, metal oxynitride, metal silicon oxide, or metal silicon oxynitride, but is not limited thereto.

The gate insulating pattern GOX may extend along the first sidewall SS11 of the first active pattern, and may extend along the first sidewall SS21 of the second active pattern. In a semiconductor memory device according to some embodiments, in cross-sectional view, the gate insulating pattern GOX between the first active pattern AP1 and the first word line WL1 may be separated from the gate insulating pattern GOX between the second active pattern AP2 and the second word line WL2. The gate insulating pattern GOX may not extend along the first surface WL_S1 of the first word line WL1 and may not extend along the first surface WL_S1 of the second word line WL2.

A gate isolation pattern GSS may be disposed on the bit line BL. The gate isolation pattern GSS may be disposed between the bit line BL and the contact pattern BC.

The gate isolation pattern GSS may be disposed between the first word line WL1 and the second word line WL2 adjacent in the second direction DR2. The first word line WL1 and the second word line WL2 may be separated by the gate isolation pattern GSS. The gate isolation pattern GSS may extend in the first direction DR1 between the first word line WL1 and the second word line WL2.

The first word line WL1 may be disposed between the gate isolation pattern GSS and the first active pattern AP1. The second word line WL2 may be disposed between the gate isolation pattern GSS and the second active pattern AP2.

The gate isolation pattern GSS may cover the first surfaces WL_S1 of the first and second word lines WL1 and WL2. The gate isolation pattern GSS may cover the second surfaces WL_S2 of the first and second word lines WL1 and WL2.

The gate isolation pattern GSS may be made of an insulating material. In an example, the gate isolation pattern GSS may include a plurality of insulating films.

A bit line contact plug 281a may be connected to the bit line BL. The bit line contact plug 281a may connect the bit line BL to the first cell connection line 281. The bit line contact plug 281a is connected to a conductive bit line.

The word line contact plug 281b may be connected to the first and second word lines WL1 and WL2. The word line contact plug 281b may connect the first and second word lines WL1 and WL2 to the first cell connection line 281.

The bit line contact plug 281a and the word line contact plug 281b may each include a conductive material.

The pad isolation pattern 245 may be disposed on the cell region element isolation film STI. The pad isolation pattern 245 may be disposed on the first and second word lines WL1 and WL2, the back gate electrodes BG, and the first and second active patterns AP1 and AP2. The first and second word lines WL1 and WL2, the back gate electrodes BG, and the first and second active patterns AP1 and AP2 may be disposed between the pad isolation pattern 245 and the bit lines BL, and between the pad isolation pattern 245 and the shielding conductive pattern SL.

The pad isolation pattern 245 may be disposed on the cell array region CAR. In plan view, the pad isolation pattern 245 may cover at least a part of the cell array region CAR. In FIGS. 2 to 5, the pad isolation pattern 245 is shown as being partially disposed on the peripheral circuit region PCR, but it is not limited thereto. In an example, the pad isolation pattern 245 may not be disposed on the peripheral circuit region PCR.

The pad isolation pattern 245 may include an outer pad isolation pattern 245_O and an inner pad isolation pattern 245_I. The outer pad isolation pattern 245_O may be disposed along the perimeter of the inner pad isolation pattern 245_I. In plan view, the outer pad isolation pattern 245_O may surround the inner pad isolation pattern 245_I. The inner pad isolation pattern 245_I may be in contact with the outer pad isolation pattern 245_O.

The inner pad isolation pattern 245_I and the outer pad isolation pattern 245_O may each include an insulating material. The inner pad isolation pattern 245_I and the outer pad isolation pattern 245_O may include at least one of silicon nitride, silicon oxynitride, or silicon oxide, but are not limited thereto. For example, the inner pad isolation pattern 245_I and the outer pad isolation pattern 245_O may each include silicon nitride.

A first interlayer insulating film 290 may be disposed on the cell region element isolation film STI. The first interlayer insulating film 290 may cover the sidewall of the pad isolation pattern 245. The first interlayer insulating film 290 includes an insulating material.

The contact patterns BC and the landing pads LP may be disposed in the pad isolation pattern 245. For example, the contact patterns BC and the landing pads LP may be disposed in the inner pad isolation pattern 245_I. The inner pad isolation pattern 245_I may be disposed along the perimeter of each of the contact patterns BC and along the perimeter of each of the landing pads LP. In plan view, the inner pad isolation pattern 245_I may surround each contact pattern BC. The inner pad isolation pattern 245_I may surround each landing pad LP. In a case that the inner pad isolation pattern 245_I is disposed along the perimeter of each of the contact patterns BC and along the perimeter of each of the landing pads LP, the landing pads LP and the contact patterns BC may not be in contact with the outer pad isolation pattern 245_O. For example, the landing pads LP may be isolated from the outer pad isolation pattern 245_O by the inner pad isolation pattern 245_I. In other words, the inner pad isolation pattern 245_I may be disposed between the landing pads LP disposed at the outermost portion and the outer pad isolation pattern 245_O.

The contact patterns BC may be disposed on the first active patterns AP1 and the second active patterns AP2. Each of the contact patterns BC may be connected to the first active pattern AP1 or the second active pattern AP2. Each of the contact patterns BC may be connected to the second surface S12 of the first active pattern or the second surface S22 of the second active pattern.

The landing pads LP may be disposed on the corresponding contact patterns BC. The landing pads LP may be disposed above the first active pattern AP1 or the second active pattern AP2 corresponding thereto. Each of the contact patterns BC may be disposed between the first active pattern AP1 and the landing pad LP or between the second active pattern AP2 and the landing pad LP.

Each of the landing pads LP may be connected to the second surface S12 of the first active pattern or the second surface S22 of the second active pattern. For example, each of the landing pads LP may be electrically connected to the first active pattern AP1 or the second active pattern AP2.

In plan view, the landing pads LP may have various shapes such as a circle, an ellipse, a rectangle, a square, a rhombus, or a hexagon. The contact pattern BC may have a shape that corresponds to the landing pad LP. That is, in plan view, if the landing pad LP is circular, the contact pattern BC may also be circular. However, the present disclosure is not limited thereto, and the landing pad LP and the contact pattern BC may have different shapes from each other.

In plan view, the landing pads LP and the contact patterns BC may be arranged in a matrix form along the first direction DR1 and the second direction DR2.

The pad block patterns LPB may be disposed in the pad isolation pattern 245. The pad block patterns LPB may be disposed along a perimeter of the landing pads LP. For example, the pad block patterns LPB may be disposed along the perimeter of an array of the landing pads LP.

The pad block patterns LPB may be disposed between the inner pad isolation pattern 245_I and the outer pad isolation pattern 245_O. For example, the pad block patterns LPB may be formed as a plurality of island shaped pad block patterns. In plan view, each pad block pattern LPB may be disposed at the boundary between the inner pad isolation pattern 245_I and the outer pad isolation pattern 245_O. For example, adjacent ones of the pad block pattern LPB may be separated by the outer pad isolation pattern 245_O and the pad block patterns LPB may be separated from the landing pads LP by the inner pad isolation pattern 245_I. Each pad block pattern LPB may be in contact with the inner pad isolation pattern 245_I and the outer pad isolation pattern 245_O. For example, the sidewall of each pad block pattern LPB may be in contact with the inner pad isolation pattern 245_I and the outer pad isolation pattern 245_O.

In a case that the pad block patterns LPB are spatially spaced apart from the landing pads LP, the inner pad isolation pattern 245_I may be disposed between the pad block pattern LPB and the landing pad LP adjacent in the first direction DR1 or the second direction DR2.

The pad block patterns LPB may include a first pad block group LPB_G1, a second pad block group LPB_G2, and edge pad block patterns LPB_E.

The first pad block group LPB_G1 may include first pad block patterns LPB_1 arranged along the first direction DR1. The first pad block patterns LPB_1 may be spaced apart in the first direction DR1. The first pad block patterns LPB_1 may be arranged along the first cell region sidewall STI_S1.

The second pad block group LPB_G2 may include second pad block patterns LPB_2 arranged along the second direction DR2. The second pad block patterns LPB_2 may be spaced apart in the second direction DR2. The second pad block patterns LPB_2 may be arranged along the second cell region sidewall STI_S2.

The edge pad block patterns LPB_E may be disposed proximate to the corners where the first cell region sidewall STI_S1 and the second cell region sidewall STI_S2 meet. For example, an edge pad block pattern LPB_E may be disposed proximate to a cell region corner STI_EP. For example, the edge pad block pattern LPB_E may be disposed inside the cell region corner STI_EP. For example, each edge pad block pattern LPB_E may be disposed proximate to a respective cell region corner of the cell region corners STI_EP. For example, a portion of the outer pad isolation pattern 245_O may be disposed between the edge pad block pattern LPB_E and the cell region corner STI_EP.

The pad block patterns LPB may include the first pad block patterns LPB_1 arranged along the first direction DR1, the second pad block patterns LPB_2 arranged along the second direction DR2, and the edge pad block patterns LPB_E. The first pad block patterns LPB_1, the second pad block patterns LPB_2, and the edge pad block patterns LPB_E may be disposed along the boundary between the inner pad isolation pattern 245_I and the outer pad isolation pattern 245_O.

The pad block patterns LPB may not be connected to the first active pattern AP1 and the second active pattern AP2. The first pad block pattern LPB_1, the second pad block pattern LPB_2, and the edge pad block pattern LPB_E may not be connected to the first active pattern AP1 or the second active pattern AP2.

The first pad block pattern LPB_1 may include a first width centerline LPB_CL1 that passes through the center of the width of the first pad block pattern LPB_1 in the first direction DR1. The first width centerline LPB_CL1 may extend in the second direction DR2. In the semiconductor memory device according to some embodiments, in plan view, the first width centerline LPB_CL1 may pass through a space between the landing pads LP adjacent in the first direction DR1.

The second pad block pattern LPB_2 may include a second width centerline LPB_CL2 that passes through the center of the width of the second pad block pattern LPB_2 in the second direction DR2. The second width centerline LPB_CL2 may extend in the first direction DR1. In the semiconductor memory device according to some embodiments, in plan view, the second width centerline LPB_CL2 may pass through a space between the landing pads LP adjacent in the second direction DR2.

The landing pads LP may include landing pad rows, each including the landing pads LP arranged in the first direction DR1. The landing pads LP may include landing pad columns, each including the landing pads LP arranged in the second direction DR2. In one example, the first pad block pattern LPB_1 may be formed across from two landing pad columns, and the second pad block pattern LPB_2 may be formed across from two landing pad rows, but they are not limited thereto. For example, the first pad block pattern LPB_1 may overlap portions of two landing pad columns in the second direction DR2, and the second pad block pattern LPB_2 may overlap portions of two landing pad rows in the first direction DR1, but they are not limited thereto. For example, an area of the pad block pattern LPB that directly faces the landing pads LP may be reduced by a width of the outer pad isolation pattern 245_O disposed between adjacent ones of the first pad block pattern LPB_1 and between adjacent ones of the second pad block pattern LPB_2.

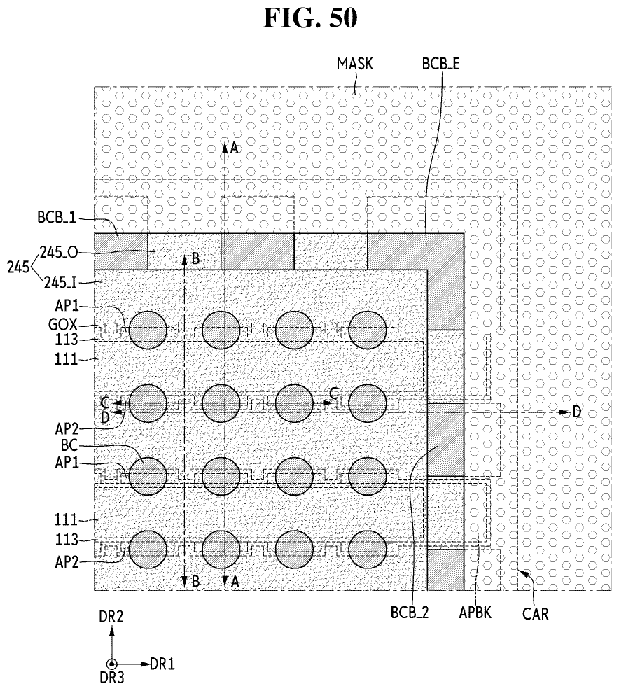

A first contact block pattern BCB_1 may be disposed at a position corresponding to the first pad block pattern LPB_1. A second contact block pattern BCB_2 may be disposed at a position corresponding to the second pad block pattern LPB_2. An edge contact block pattern BCB_E (see FIG. 50) may be disposed at a position corresponding to the edge pad block pattern LPB_E.

The first pad block pattern LPB_1, the second pad block pattern LPB_2, and the edge pad block pattern LPB_E may be disposed at the same height level as the landing pads LP. In the manufacturing process, the pad block patterns LPB may be formed simultaneously with the landing pads LP. The first contact block pattern BCB_1, the second contact block pattern BCB_2, and the edge contact block pattern BCB_E (see FIG. 50) may be disposed at the same height level as the contact patterns BC.

The contact pattern BC, the first contact block pattern BCB_1, and the second contact block pattern BCB_2 may include a conductive material. The contact pattern BC, the first contact block pattern BCB_1 and the second contact block pattern BCB_2 may include, for example, at least one of doped polysilicon, conductive metal nitride, conductive metal silicon nitride, metal carbonitride, conductive metal silicide, conductive metal oxide, conductive metal oxynitride, a 2D material, or metal. As an example, the contact pattern BC, the first contact block pattern BCB_1, and the second contact block pattern BCB_2 may include doped polysilicon.

The landing pad LP and the pad block pattern LPB may include a conductive material. The landing pad LP and the pad block pattern LPB may include, for example, at least one of doped polysilicon, conductive metal nitride, conductive metal silicon nitride, metal carbonitride, conductive metal silicide, conductive metal oxide, conductive metal oxynitride, a 2D material, or metal. In one example, the landing pad LP and the pad block pattern LPB may include a conductive material containing metal.

In FIG. 7, FIG. 8, and FIG. 9, the pad isolation pattern 245 may include a upper surface 245_US facing the data storage patterns DSP. The landing pad LP may include a upper surface LP_US facing the data storage patterns DSP. The pad block pattern LPB may include a upper surface LPB_US facing the data storage patterns DSP. The upper surface 245_US of the pad isolation pattern may lie on the same plane as the upper surface LP_US of the landing pad and the upper surface LPB_US of the pad block pattern.

The thickness of the landing pad LP may be the same as the thickness of the pad block pattern LPB. The thickness of the contact pattern BC may be the same as the thickness of the second contact block pattern BCB_2.

In FIG. 7 and FIG. 8, the width of the contact pattern BC and the width of the landing pad LP may be constant as they move away from the gate isolation pattern GSS. In FIG. 9, the width of the contact pattern BC and the width of the landing pad LP may decrease as they move away from the gate isolation pattern GSS.

In FIG. 7, a thickness t1 of the pad isolation pattern 245 in the third direction DR3 may be equal to the sum of a thickness t22 of the landing pad LP in the third direction DR3 and a thickness t21 of the contact pattern BC in the third direction DR3.

In FIG. 8, a thickness t1 of the pad isolation pattern 245 in the third direction DR3 may be greater than the sum of a thickness t22 of the landing pad LP in the third direction DR3 and a thickness t21 of the contact pattern BC in the third direction DR3. In the process of forming the contact pattern BC, the gate isolation pattern GSS may be partially etched.

A bridge between the landing pads LP and the pad block pattern may lead to a reduction in the reliability and performance of the semiconductor memory device. For example, in a case that a single pad block pattern is disposed around the landing pads LP, a bridge may occur between the outermost landing pads LP and the pad block pattern. That is, the outermost landing pads LP may be connected to the pad block pattern and the reliability and performance of the semiconductor memory device may be affected.

In the semiconductor memory device according to some embodiments, an area where a pad block pattern LPB faces the landing pads LP disposed above active patterns may be reduced, and an aera for forming a bridge between the outermost landing pad LP and the pad block pattern LPB may be reduced. For example, in a case that the pad block pattern LPB includes a plurality of island shaped pad block patterns disposed around an array of the landing pads LP, a bridge between the outermost landing pads LP and the pad block patterns LPB may be inhibited or prevented. Further, in a case that the outer pad isolation pattern 245_O protrudes toward the landing pads LP, separating the island shaped pad block patterns, a bridge between the landing pads LP and the pad block pattern LPB may be inhibited or prevented. Moreover, in a case that the pad block patterns LPB are spaced apart by the outer pad isolation pattern 245_O, a short circuit caused by a bridge between the outermost landing pad LP and the pad block pattern LPB may not occur.

An etch stop film 247 may be disposed on the landing pads LP, the pad block patterns LPB, the pad isolation pattern 245, and the first interlayer insulating film 290. The etch stop film 247 may extend along the upper surface LP_US of the landing pad, the upper surface LPB_US of the pad block pattern, and the upper surface 245_US of the pad isolation pattern. The etch stop film 247 may be made of an insulating material.

The data storage patterns DSP may be disposed above the first and second word lines WL1 and WL2 and the back gate electrodes BG. The data storage patterns DSP may be disposed above the second surfaces WL_S2 of the first and second word lines WL1 and WL2 and the second surface BG_S2 of the back gate electrode BG.

The data storage patterns DSP may be disposed above the first and second active patterns AP1 and AP2. For example, the data storage patterns DSP may be respectively disposed on the landing pads LP. The data storage patterns DSP may be connected to the landing pads LP. Each of the data storage patterns DSP may be in contact with the landing pad LP corresponding thereto.

The data storage patterns DSP may be respectively electrically connected to the first and second active patterns AP1 and AP2. The data storage patterns DSP may be respectively electrically connected to the first and second active patterns AP1 and AP2 with the landing pads LP disposed therebetween. For example, the landing pads LP may improve an electrical coupling between the data storage patterns DSP and the first and second active patterns AP1 and AP2. For example, the landing pads LP may improve electrical connectivity between the data storage patterns DSP and the first and second active patterns AP1 and AP2, reducing resistance, and ensuring reliable signal transmission. As shown in FIG. 2, the data storage patterns DSP may be arranged in a matrix form along the first direction DR1 and the second direction DR2.

In one example, the data storage patterns DSP may be capacitors. The data storage patterns DSP may include a capacitor dielectric film 253 interposed between storage electrodes 251 and a plate electrode 255. The storage electrodes 251 may penetrate the etch stop film 247. For example, the storage electrode 251 may be in contact with the upper surface LP_US of the landing pad. In plan view, the storage electrode 251 may have various shapes, such as a circle, an ellipse, a rectangle, a square, a rhombus, or a hexagon.

Each of the storage electrode 251 and the plate electrode 255 may include a conductive material, and may include, for example, at least one of a conductive semiconductor material, conductive metal nitride, conductive metal silicon nitride, metal carbonitride, conductive metal silicide, conductive metal oxide, conductive metal oxynitride, a 2D material, or metal. The capacitor dielectric film 253 may include at least one of a ferroelectric material, an antiferroelectric material, or a paraelectric material. For example, the capacitor dielectric film 253 may include one of a ferroelectric material, an antiferroelectric material, a paraelectric material, a combination of a ferroelectric material and an antiferroelectric material, a combination of a ferroelectric material and a paraelectric material, a combination of a paraelectric material or an antiferroelectric material, or a combination of a ferroelectric material, an antiferroelectric material, or a paraelectric material.

On the other hand, the data storage patterns DSP may be variable resistance patterns that can be switched into different resistance states by an electrical pulse applied to a memory element. For example, the data storage patterns DSP may include a phase-change material whose crystalline state changes depending on the amount of current, perovskite compounds, transition metal oxide, magnetic materials, ferromagnetic materials, or antiferromagnetic materials.

In the semiconductor memory device according to some embodiments, the data storage patterns DSP may be connected to the respective landing pads LP. In other words, the landing pad LP may be connected to the storage electrode 251 of the data storage pattern DSP.

The data storage patterns DSP may not be disposed on the pad block patterns LPB. The data storage patterns DSP may not be connected to the pad block patterns LPB. In other words, the storage electrode 251 is not disposed on the pad block patterns LPB and is not connected to the pad block patterns LPB. For example, the storage electrode 251 is disposed apart from the pad block patterns LPB in the first direction DR1 and the second direction DR2, and disconnected from the pad block patterns LPB.

A second interlayer insulating film 291 may be disposed on the data storage patterns DSP. The second interlayer insulating film 291 includes an insulating material.

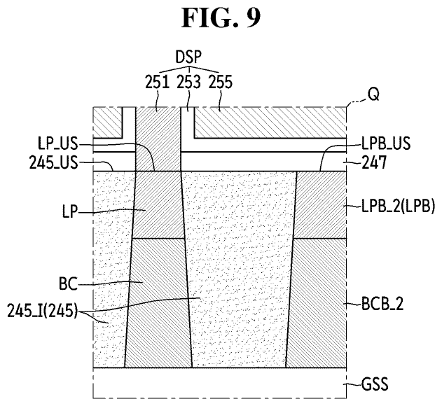

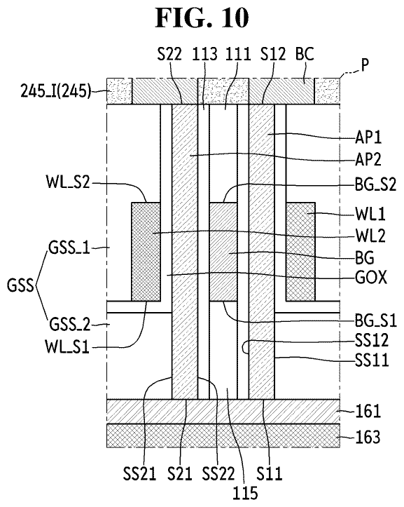

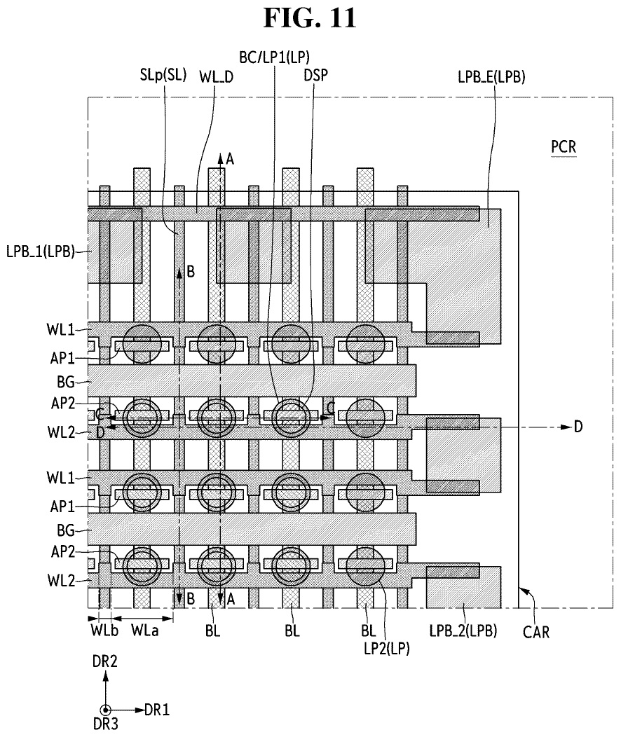

FIG. 10 is a diagram illustrating a semiconductor memory device according to some embodiments. FIG. 11, FIG. 12, and FIG. 13 are diagrams illustrating a semiconductor memory device according to some embodiments. For simplicity of description, the following description will focus on differences from the description with reference to FIGS. 1 to 9.

For reference, FIG. 10 is an enlarged view of part P of FIG. 4. FIG. 12 is a cross-sectional view taken along lines A-A and B-B of FIG. 11. FIG. 13 is a cross-sectional view taken along lines C-C and D-D of FIG. 11.

Referring to FIG. 10, in the semiconductor memory device according to some embodiments, the gate isolation pattern GSS may include a first gate isolation pattern GSS_1 and a second gate isolation pattern GSS_2.

The second gate isolation pattern GSS_2 may be disposed between the first word line WL1 and the bit line BL, and between the second word line WL2 and the bit line BL. The gate shielding pattern 145 may be disposed on the first surfaces WL_S1 of the first and second word lines WL1 and WL2.

The second gate isolation pattern GSS_2 may include a upper surface and a lower surface which may be disposed opposite to each other in the third direction DR3. The lower surface of the second gate isolation pattern GSS_2 may face the bit line BL. The first word line WL1 and the second word line WL2 may be disposed above the upper surface of the second gate isolation pattern GSS_2. The gate insulating pattern GOX may extend along the upper surface of the second gate isolation pattern GSS_2.

The first gate isolation pattern GSS_1 may be disposed above the second gate isolation pattern GSS_2. The first gate isolation pattern GSS_1 may be disposed between the second gate isolation pattern GSS_2 and the pad isolation pattern 245.

The gate insulating pattern GOX may be disposed between the second gate isolation pattern GSS_2 and the first word line WL1, and between the second gate isolation pattern GSS_2 and the second word line WL2. The gate insulating pattern GOX may extend along the first surface WL_S1 of the first word line WL1 and the first surface WL_S1 of the second word line WL2.

In cross-sectional view, the gate insulating pattern GOX between the first active pattern AP1 and the first word line WL1 may be connected to the gate insulating pattern GOX between the second active pattern AP2 and the second word line WL2. In an example, gate insulating pattern GOX between the first active pattern AP1 and the first word line WL1 may be separated from the gate insulating pattern GOX between the second active pattern AP2 and the second word line WL2.

Referring to FIG. 11, FIG. 12, and FIG. 13, in the semiconductor memory device according to some embodiments, the landing pads LP may include first landing pads LP1 and second landing pads LP2.

The second landing pads LP2 may be disposed around the first landing pads LP1. The second landing pads LP2 may be disposed between the first landing pads LP1 and the first pad block patterns LPB_1, and between the first landing pads LP1 and the second pad block patterns LPB_2.

The first landing pads LP1 may be connected to the first active patterns AP1 or the second active patterns AP2. The first landing pads LP1 may be connected to the data storage patterns DSP.

The second landing pads LP2 may be connected to the first active patterns AP1 or the second active patterns AP2. The second landing pads LP2 may not be connected to the data storage patterns DSP.

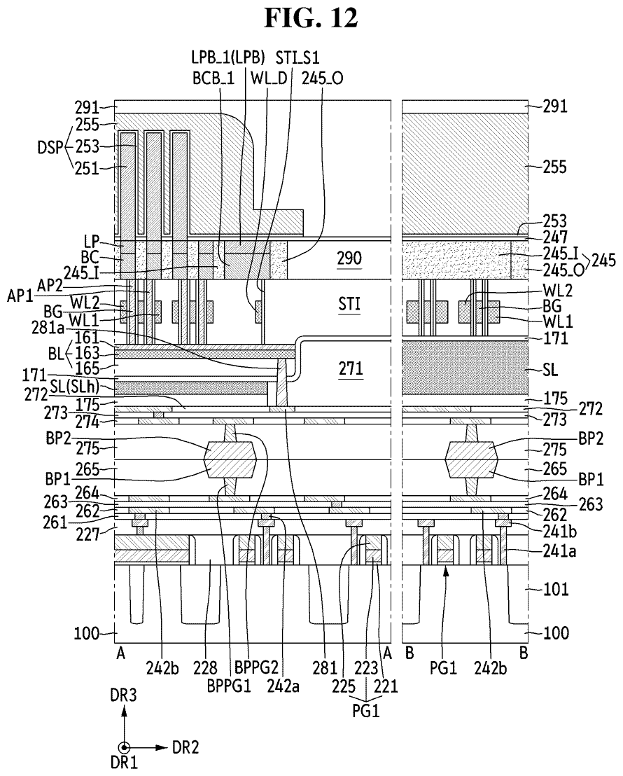

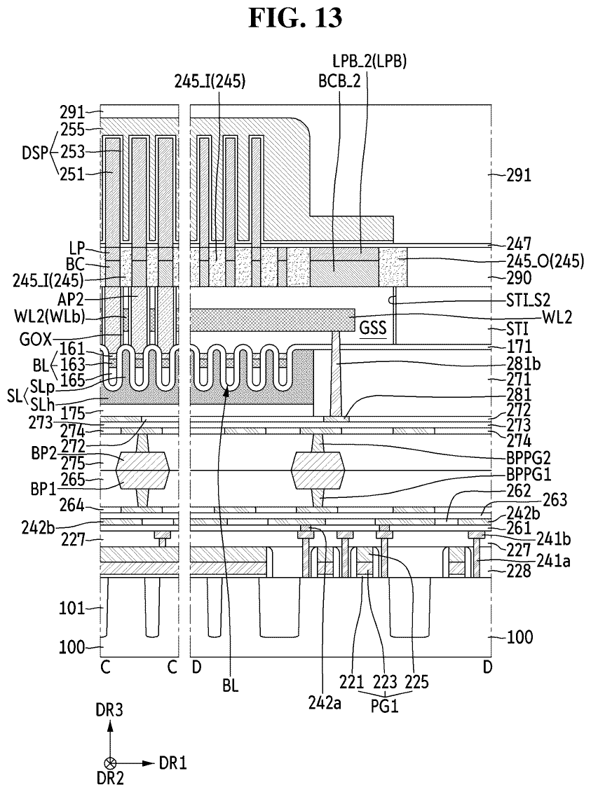

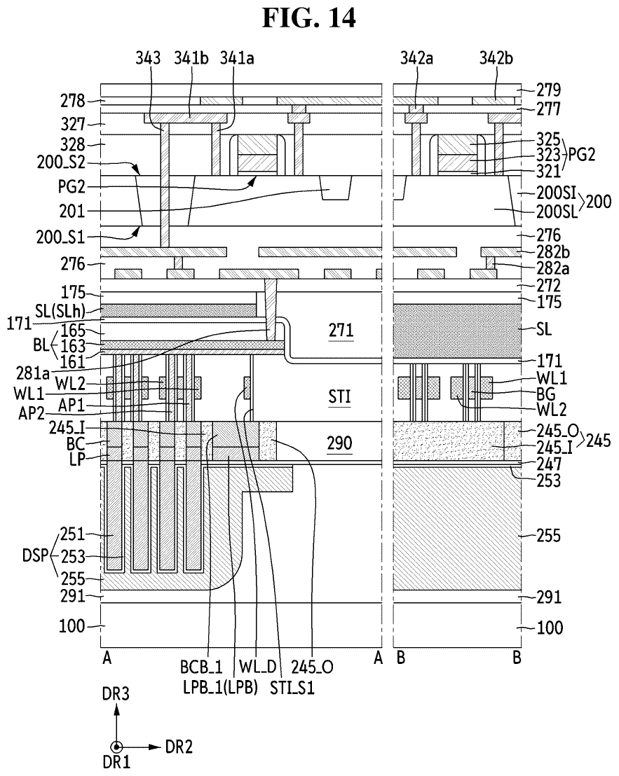

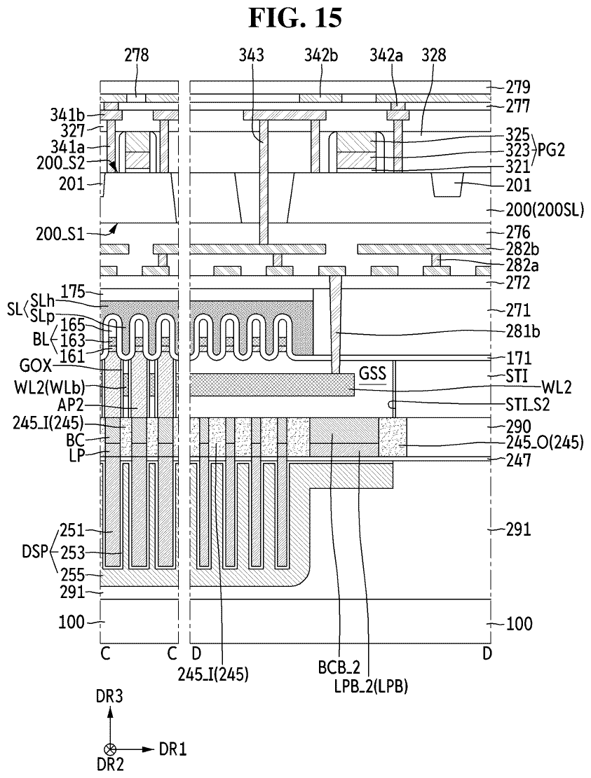

FIG. 14 and FIG. 15 are diagrams illustrating a semiconductor memory device according to some embodiments. For simplicity of description, the following description will focus on differences from the description with reference to FIGS. 1 to 9.

Referring to FIG. 14 and FIG. 15, the semiconductor memory device according to some embodiments may further include a peri-active substrate 200, a second peri-gate structure PG2, and a peri-connection through plug 343.

The data storage patterns DSP may be disposed between the substrate 100 and the bit lines BL. The second cell interlayer insulating film 272 may be disposed above the bit line BL and the shielding conductive pattern SL.

A sixth cell interlayer insulating film 276 may be disposed on the second cell interlayer insulating film 272. The sixth cell interlayer insulating film 276 includes an insulating material.

A second cell connection via 282a and a second cell connection line 282b may be disposed on the second cell interlayer insulating film 272. The second cell connection via 282a and the second cell connection line 282b may be disposed in the sixth cell interlayer insulating film 276. Although it is illustrated that the plurality of second cell connection lines 282b disposed at different metal levels are disposed in the sixth cell interlayer insulating film 276, the present disclosure is not limited thereto.

The second cell connection via 282a and the second cell connection line 282b may each include a conductive material. The second cell connection via 282a and the second cell connection line 282b are shown as different films, but they are not limited thereto.

The bit line contact plug 281a may connect the bit line BL to the first cell connection line 282a. The word line contact plug 281b may connect the first and second word lines WL1 and WL2 to the first cell connection line 282a.

The peri-active substrate 200 may be disposed above the second cell connection line 282b. The peri-active substrate 200 may be spaced apart from the substrate 100 in the third direction DR3. The second cell connection via 282a and the second cell connection line 282b may be disposed between the substrate 100 and the peri-active substrate 200.

The peri-active substrate 200 includes a peri-semiconductor film 200SL and a peri-semiconductor isolation film 200SI. For example, the peri-active substrate 200 may include the plurality of peri-semiconductor isolation films 200SI.

The peri-semiconductor film 200SL contains a semiconductor material. The peri-semiconductor film 200SL may include, for example, silicon, silicon germanium, indium antimonide, lead tellurium compound, indium arsenide, indium phosphide, gallium arsenide, or gallium antimonide, but is not limited thereto. In the following description, the peri-semiconductor film 200SL is described as a silicon film containing silicon.

The peri-semiconductor isolation film 200SI includes an insulating material. The peri-semiconductor isolation film 200SI is shown as a single film, but this is merely for simplicity of description and the present disclosure is not limited thereto.

The peri-active substrate 200 may include a first surface 200_S1 and a second surface 200_S2, which may be disposed opposite to each other in the third direction DR3. The first surface 200_S1 of the peri-active substrate may face the substrate 100 and the second cell connection line 282b.

The first surface 200_S1 of the peri-active substrate and the second surface 200_S2 of the peri-active substrate each include the peri-semiconductor film 200SL and the peri-semiconductor isolation film 200SI. In other words, the first surface 200_S1 of the peri-active substrate and the second surface 200_S2 of the peri-active substrate may each be defined by the peri-semiconductor film 200SL and the peri-semiconductor isolation film 200SI.

A second element isolation film 201 may be disposed in the peri-semiconductor film 200SL. The second element isolation film 201 may be formed on the second surface 200_S2 of the peri-active substrate. The second element isolation film 201 may not extend to the first surface 200_S1 of the peri-active substrate. The thickness of the second element isolation film 201 in the third direction DR3 may be smaller than the thickness of the peri-semiconductor isolation film 200SI in the third direction DR3. The second element isolation film 201 includes an insulating material.

The second peri-gate structure PG2 may be disposed on the peri-semiconductor film 200SL. The second peri-gate structure PG2 may be disposed on the second surface 200_S2 of the peri-active substrate.

The second peri-gate structure PG2 may include a second peri-gate insulating film 321, a second peri-lower conductive pattern 323, and a second peri-upper conductive pattern 325. The second peri-gate insulating film 321 may include silicon oxide, silicon oxynitride, a high-k insulating material having a dielectric constant higher than silicon oxide, or a combination thereof. The second peri-lower conductive pattern 323 and the second peri-upper conductive pattern 325 may each include at least one of a doped semiconductor material, conductive metal nitride, conductive metal silicon nitride, metal carbonitride, conductive metal silicide, conductive metal oxide, a 2D material, or metal. Although the second peri-gate structure PG2 is illustrated as including a plurality of conductive patterns, it is not limited thereto.

In the semiconductor memory device according to some embodiments, the bit lines BL and the data storage patterns DSP may be disposed between the substrate 100 and the second peri-gate structure PG2.

A third peri-lower insulating film 327 and a fourth peri-lower insulating film 328 may be disposed on the second surface 200_S2 of the peri-active substrate. Each of the third peri-lower insulating film 327 and the fourth peri-lower insulating film 328 includes an insulating material.

A second peri-contact plug 341a and a second peri-wiring line 341b may be disposed in the third peri-lower insulating film 327 and the fourth peri-lower insulating film 328. The second peri-contact plug 341a and the second peri-wiring line 341b may be disposed on the second surface 200_S2 of the peri-active substrate.

The second peri-contact plug 341a and the second peri-wiring line 341b may be connected to a second source/drain region disposed on at least one side of the second peri-gate structure PG2. The second peri-contact plug 341a and the second peri-wiring line 341b may be connected to the conductive patterns 323 and 325 of the second peri-gate structure PG2. For example, the second peri-wiring line 341b may be a wiring line closest to the second peri-gate structure PG2 in the third direction DR3.

Although the second peri-contact plug 341a and the second peri-wiring line 341b are shown as different films, they are not limited thereto. Each of the second peri-contact plug 341a and the second peri-wiring line 341b includes a conductive material.

The peri-connection through plug 343 may be disposed between the second peri-wiring line 341b and the second cell connection line 282b. The peri-connection through plug 343 may connect the second peri-wiring line 341b to the second cell connection line 282b.

The peri-connection through plug 343 may penetrate the peri-active substrate 200. For example, the peri-connection through plug 343 may penetrate the peri-semiconductor isolation film 200SI. The peri-connection through plug 343 includes a conductive material.

A sixth peri-upper insulating film 277, a seventh peri-upper insulating film 278, and an eighth peri-upper insulating film 279 may be disposed on the second peri-contact plug 341a and the second peri-wiring line 341b. Each of the sixth to eighth peri-upper insulating films 277, 278, and 279 includes an insulating material. In an example, an insulating film formed as a single film may be disposed on the second peri-contact plug 341a and the second peri-wiring line 341b.

A second peri-connection structure may include a second peri-connection via 342a and a second peri-connection line 342b. The second peri-connection structure may be connected to the second peri-wiring line 341b. Each of the second peri-connection via 342a and the second peri-connection line 342b may include a conductive material.

Although the second peri-connection via 342a and the second peri-connection line 342b are shown as different films, they are not limited thereto. The second peri-connection structure is shown as including the second peri-connection line 342b disposed at a single metal level, but this is merely for simplicity of description and the present disclosure is not limited thereto. For example, the second peri-connection structure may include the plurality of second peri-connection lines 342b disposed at two different metal levels.

In an example, the bit lines BL may be disposed between the data storage patterns DSP and the substrate 100. In this case, the sixth cell interlayer insulating film 276 may be disposed on the data storage patterns DSP.

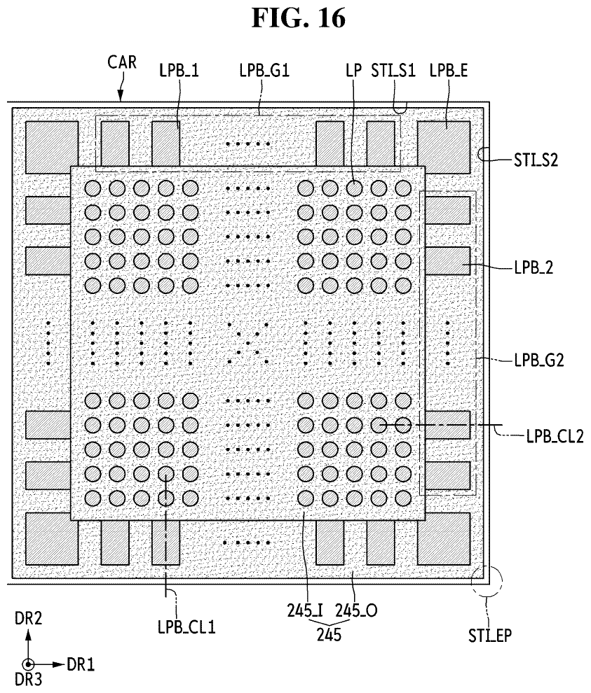

FIGS. 16 to 19 are diagrams each illustrating a semiconductor memory device according to some embodiments. For simplicity of description, the following description will focus on differences from the description with reference to FIGS. 1 to 9.

For reference, FIG. 16 is a diagram illustrating the shape and positional relationship of the landing pads, the pad block patterns, and the pad isolation pattern around them of FIG. 2.

Referring to FIG. 16, in the semiconductor memory device according to some embodiments, in plan view, the first width centerline LPB_CL1 may pass through the landing pads LP arranged in the second direction DR2.

In plan view, the second width centerline LPB_CL2 may pass through the landing pads LP arranged in the first direction DR1. For example, the first pad block pattern LPB_1 may overlap one landing pad column in the second direction DR2, and the second pad block pattern LPB_2 may overlap one landing pad row in the first direction DR1, but they are not limited thereto. Further, adjacent ones of the first pad block pattern LPB_1 may spaced apart from each other, and adjacent ones of the second pad block pattern LPB_2 may spaced apart from each other. For example, at least a width of a landing pad column may separate adjacent ones of the first pad block pattern LPB_1 in the first direction DR1 and at least a width of a landing pad row may separate adjacent ones of the second pad block pattern LPB_2 in the second direction DR2, but they are not limited thereto. For example, an area of the pad block pattern LPB that directly faces the landing pads LP may be reduced by a width of the outer pad isolation pattern 245_O disposed between adjacent ones of the first pad block pattern LPB_1 and between adjacent ones of the second pad block pattern LPB_2.

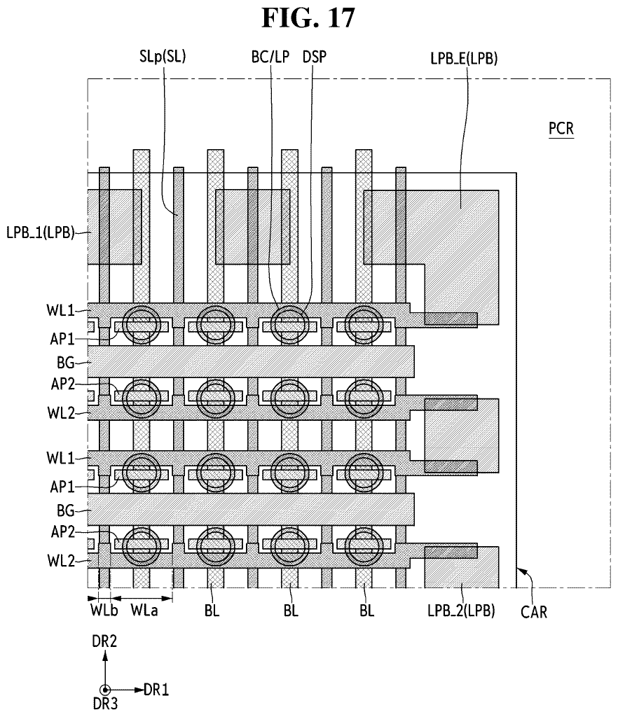

Referring to FIG. 17, in the semiconductor memory device according to some embodiments, the dummy word line WL_D (see FIG. 2) may not be disposed along the boundary of the cell array region CAR.

The dummy word line WL_D (see FIG. 2) extending along the first cell region sidewall STI_S1 of the cell region element isolation film STI is not disposed in the cell region element isolation film STI.

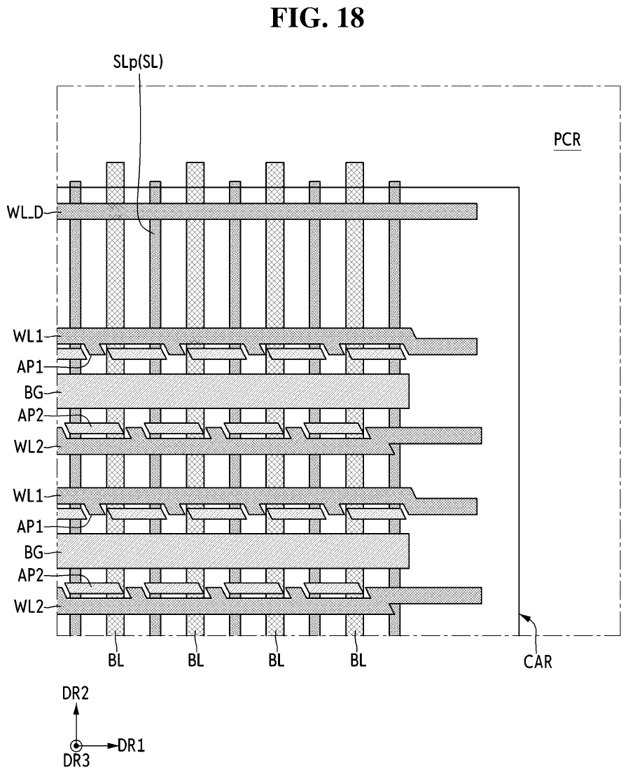

Referring to FIG. 18, in the semiconductor memory device according to some embodiments, the first and second active patterns AP1 and AP2 may be alternately arranged in an oblique direction with respect to the first and second directions DR1 and DR2.

In plan view, each of the first and second active patterns AP1 and AP2 may have a parallelogram shape or a rhombus shape. In a case that the first and second active patterns AP1 and AP2 are disposed in the oblique direction, it may be possible to reduce coupling between the first and second active patterns AP1 and AP2 facing each other in the second direction DR2.

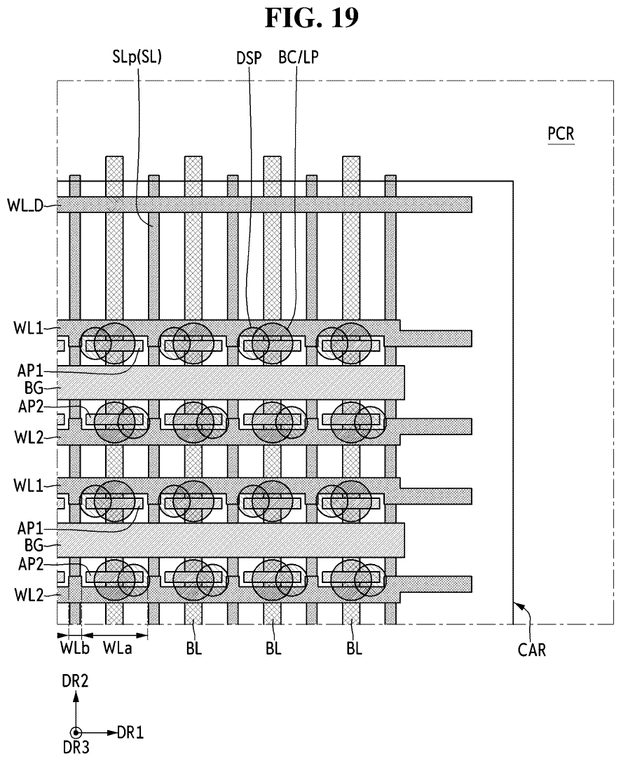

Referring to FIG. 19, in the semiconductor memory device according to some embodiments, the data storage patterns DSP may be misaligned with the landing pads LP in plan view.

Each data storage pattern DSP may be in contact with a part of the landing pad LP.

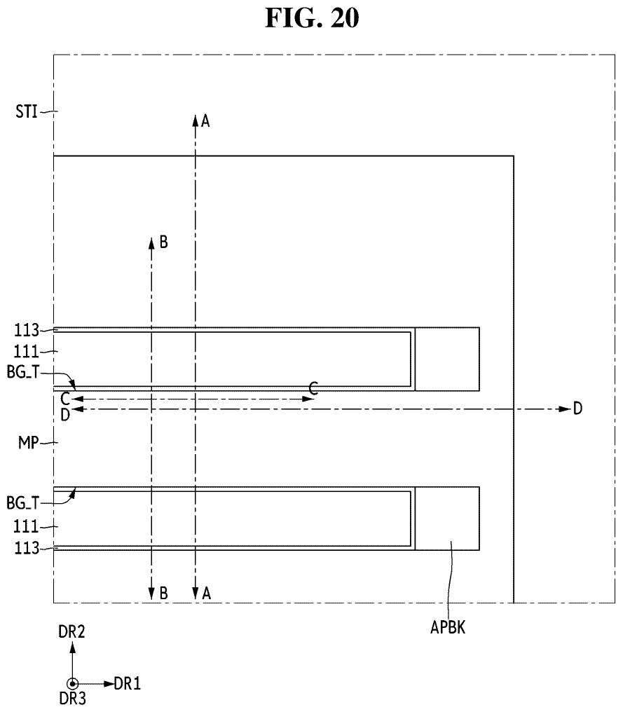

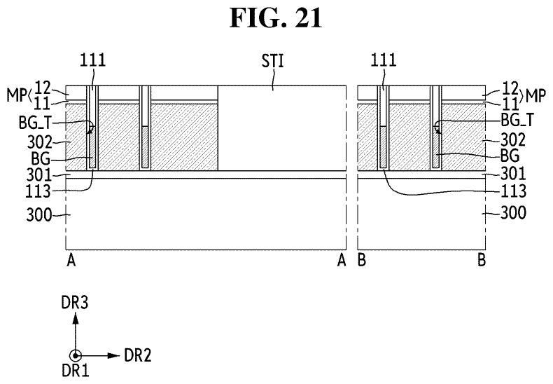

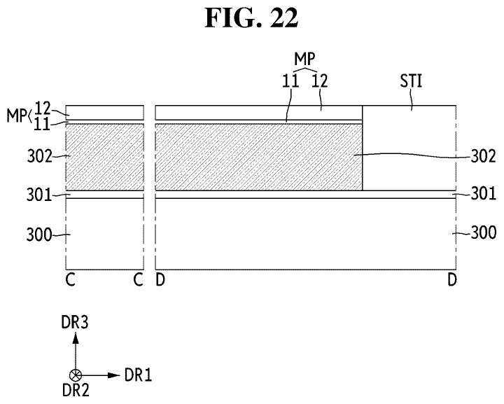

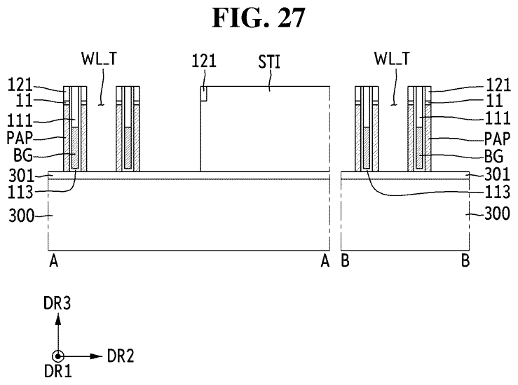

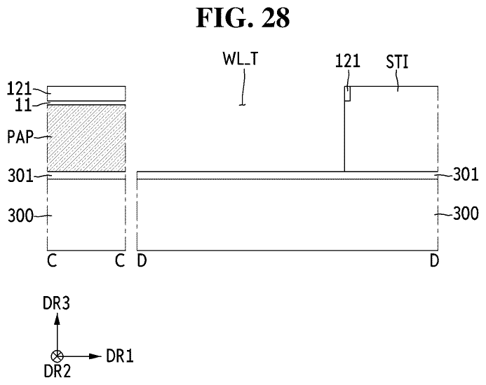

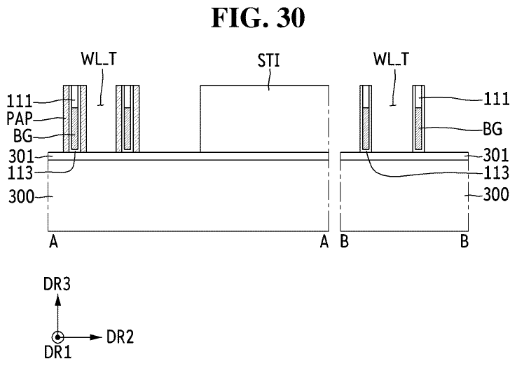

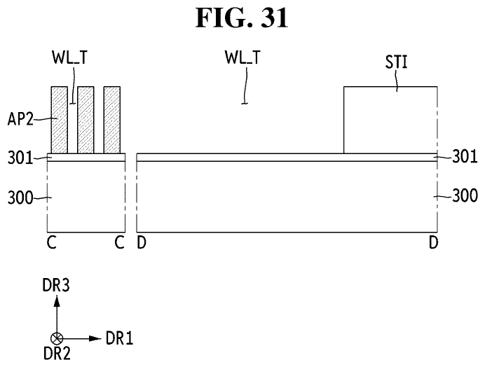

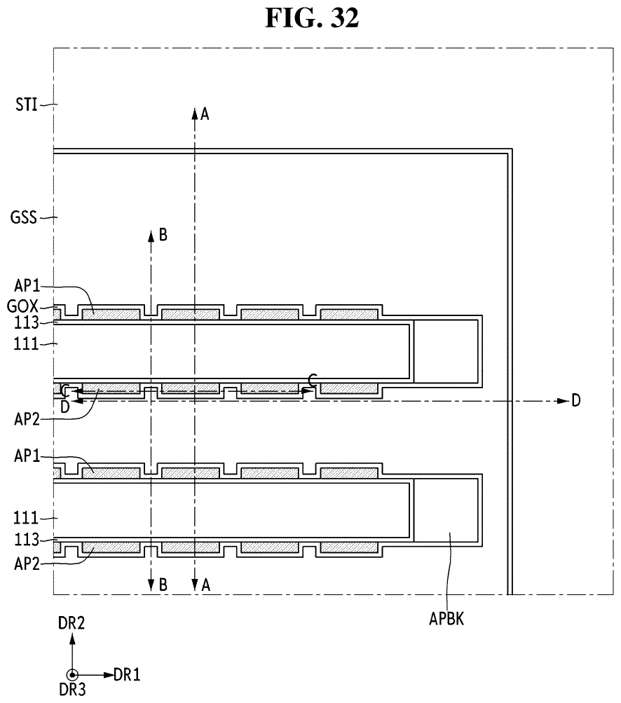

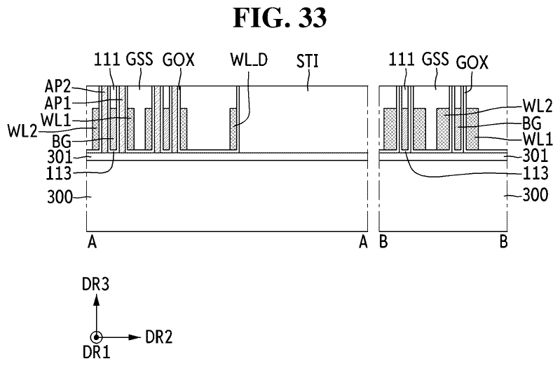

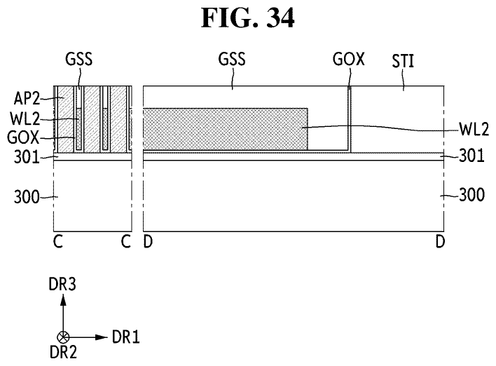

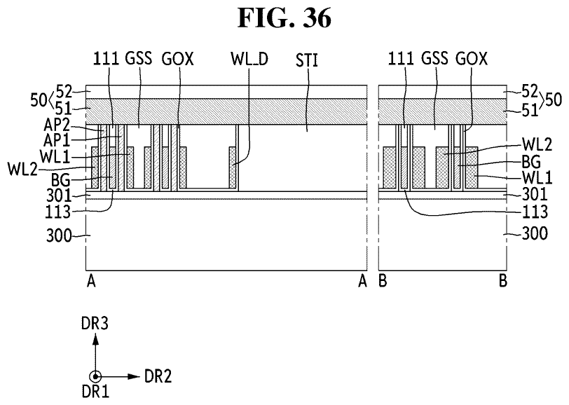

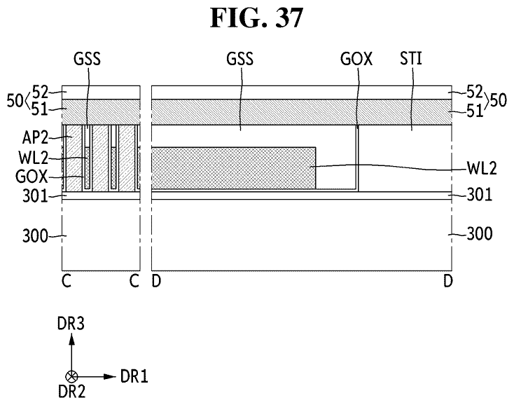

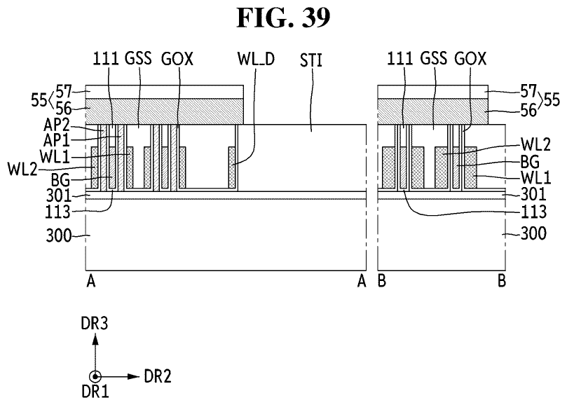

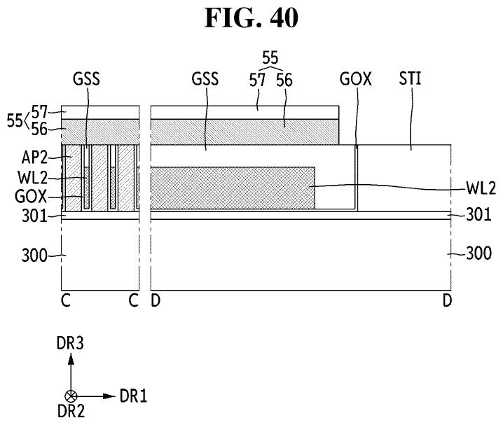

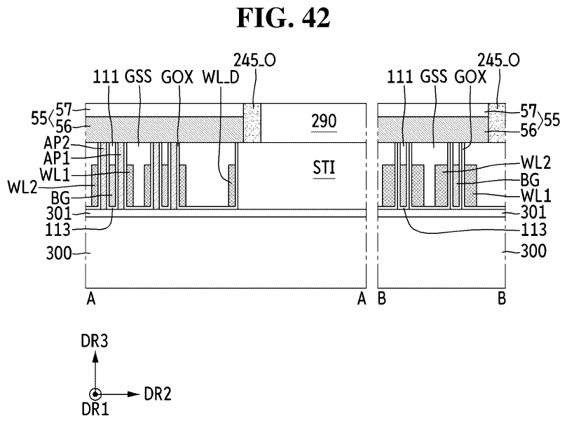

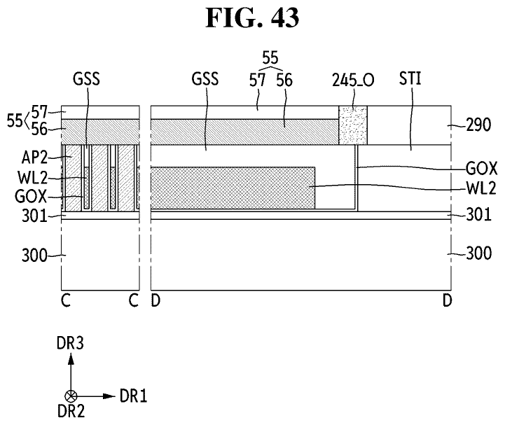

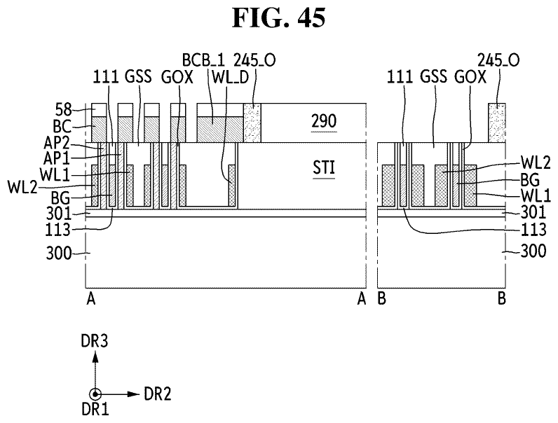

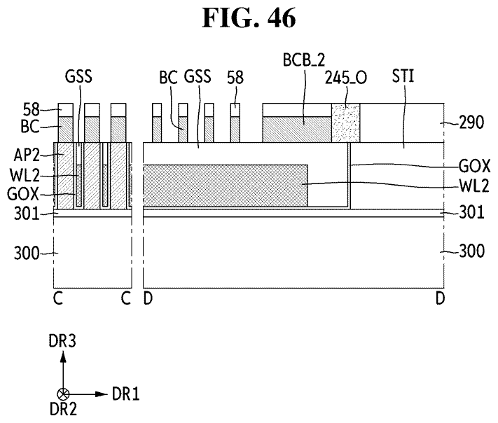

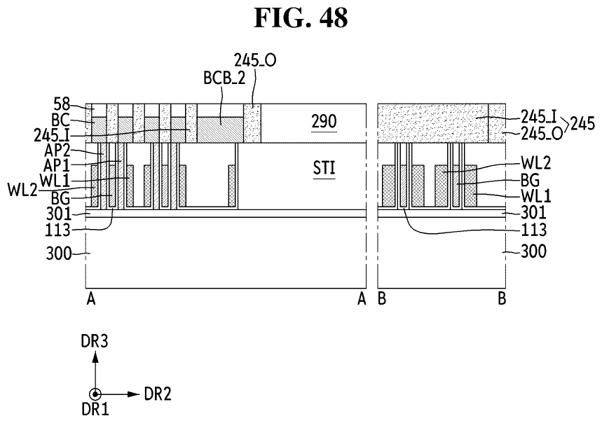

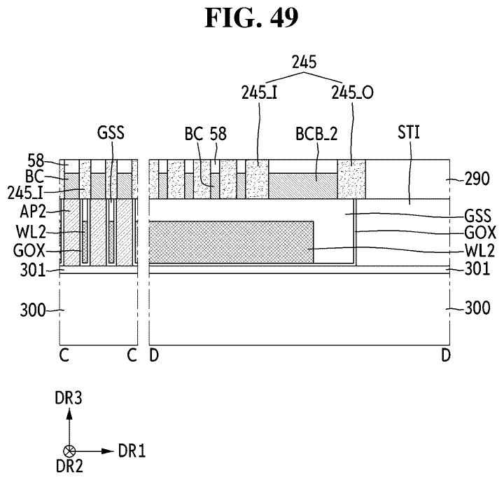

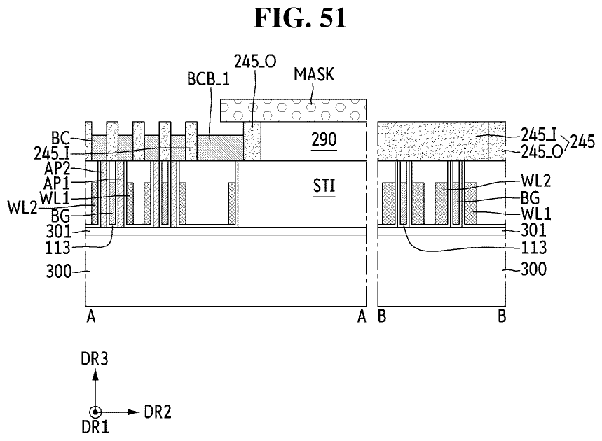

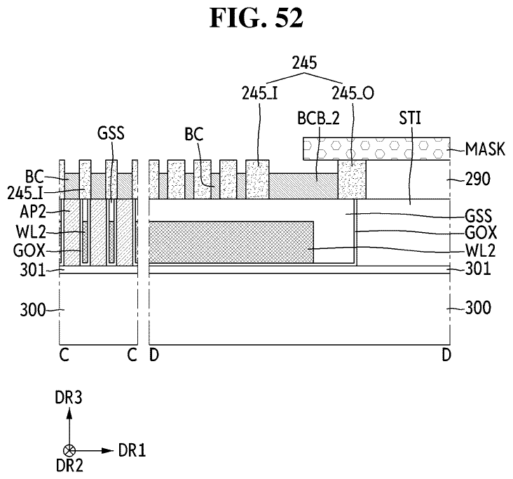

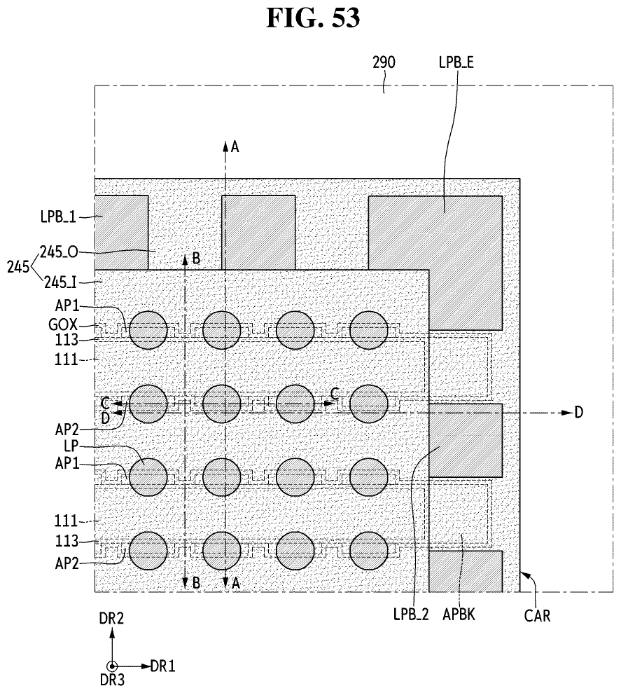

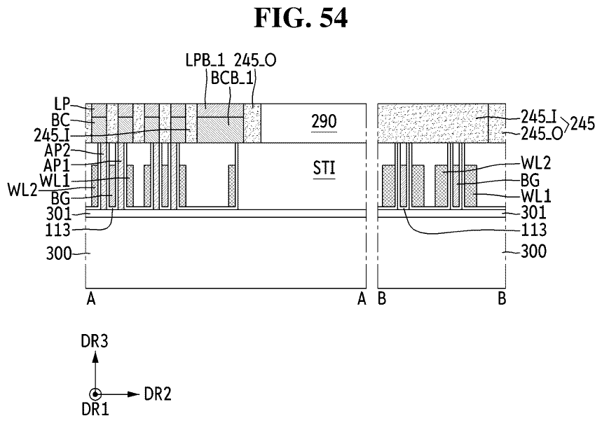

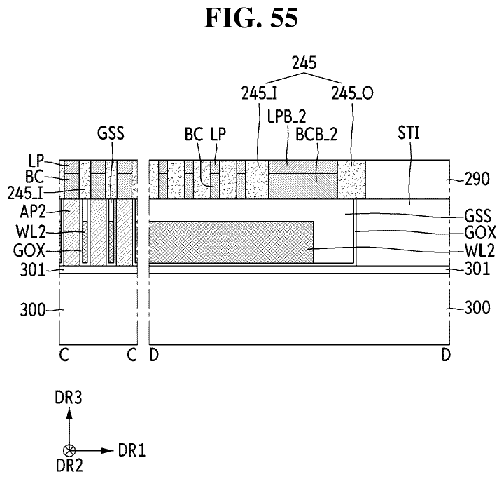

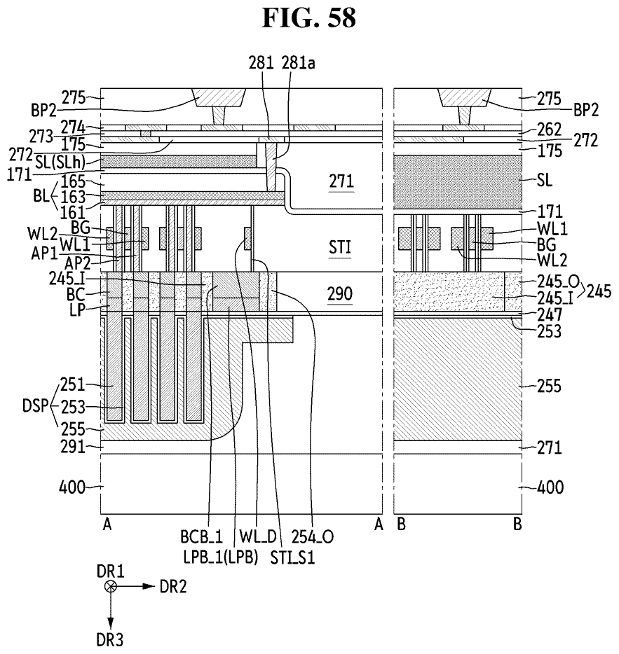

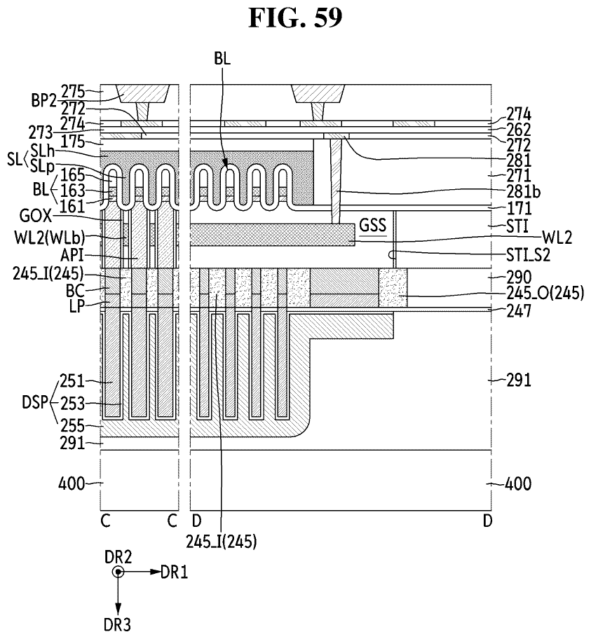

FIGS. 20 to 59 are views illustrating intermediate steps for explaining a method for fabricating a semiconductor memory device according to some embodiments. For example, a semiconductor memory device according to some embodiments and described with reference to FIGS. 1 to 9 may be fabricated according to a method illustrated in FIGS. 20 to 59.

Referring to FIGS. 20 to 22, a sub-substrate structure including a first sub-substrate 300, a buried insulating layer 301 and an active layer 302 may be provided.

The buried insulating layer 301 and the active layer 302 may be provided on the first sub-substrate 300. The first sub-substrate 300, the buried insulating layer 301, and the active layer 302 may be a silicon-on-insulating film substrate (i.e., an SOI substrate).

The first sub-substrate 300 may include the cell array region CAR and the peripheral circuit region PCR. The first sub-substrate 300 may be, for example, a silicon substrate, a germanium substrate, and/or a silicon-germanium substrate.

The buried insulating layer 301 may be a buried oxide (BOX) formed by a separation by implanted oxygen (SIMOX) method or a bonding and layer transfer method. Alternatively, the buried insulating layer 301 may be an insulating film formed by a chemical vapor deposition (CVD) method. The buried insulating layer 301 may include, for example, a silicon oxide film, a silicon nitride film, a silicon oxynitride film, and/or a low dielectric constant insulating film.

The active layer 302 may be a single crystal semiconductor layer. The active layer 302 may be, for example, a single crystal silicon substrate, a germanium substrate, and/or a silicon-germanium substrate. The active layer 302 may have first and second surfaces that may be disposed opposite to each other in the third direction DR3. The second surface of the active layer 302 may be disposed in contact with the buried insulating layer 301.

A mask pattern MP may be formed on the active layer 302. The mask pattern MP may include a lower mask film 11 and an upper mask film 12 that are sequentially stacked. The upper mask film 12 may be formed of a material having etching selectivity with respect to the lower mask film 11. For example, the lower mask film 11 may include silicon oxide, and the upper mask film 12 may include silicon nitride, but the present disclosure is not limited thereto.

The cell region element isolation film STI may be formed in the active layer 302 of the peripheral circuit region PCR. The cell region element isolation film STI may be formed by patterning the active layer 302 of the peripheral circuit region PCR to form an element isolation trench that exposes the buried insulating layer 301, and then burying an insulating material in the element isolation trench. The cell region element isolation film STI may be formed to define the cell array region CAR. The upper surface of the cell region element isolation film STI may be substantially coplanar with the upper surface of the mask pattern MP.

A plurality of active pattern isolation structures APBK may be formed in the active layer 302. The active pattern isolation structure APBK may be formed in the cell array region CAR. The active pattern isolation structures APBK may be arranged in the second direction DR2. The active pattern isolation structure APBK may include, for example, silicon oxide.

The active pattern isolation structure APBK may be spaced apart from the cell region element isolation film STI. In an example, the active pattern isolation structure APBK may be formed to be in contact with the cell region element isolation film STI.

In plan view, the active pattern isolation structure APBK is shown as being rectangular, but it is not limited thereto. In an example, the active pattern isolation structure APBK may have a shape such as a quadrilateral with rounded corners, an ellipse, or a circle.

In an example, before the mask pattern MP is formed, the active pattern isolation structure APBK may be formed in the active layer 302. In this case, the mask pattern MP may be formed on the active pattern isolation structure APBK.

The active layer 302 of the cell array region CAR may be anisotropically etched. Accordingly, back gate trenches BG_T extending in the first direction DR1 may be formed in the active layer 302 of the cell array region CAR. The back gate trenches BG_T may expose the buried insulating layer 301. The back gate trenches BG_T may be spaced apart at predetermined intervals in the second direction DR2. The back gate trenches BG_T may respectively meet the active pattern isolation structures APBK. The back gate trench BG_T may extend in the first direction DR1 from the active pattern isolation structure APBK.

In an example, at least a part of the buried insulating layer 301 may be removed while the back gate trenches BG_T are formed.

The back gate insulating pattern 113 and the back gate electrodes BG may be formed in the back gate trench BG_T. The back gate insulating pattern 113 may be in contact with the active pattern isolation structure APBK.

More specifically, the back gate insulating pattern 113 may be formed along the sidewall and the lower surface of the back gate trench BG_T and the upper surface of the mask pattern MP. A back gate conductive film may be formed on the back gate insulating pattern 113. The back gate conductive film may be disposed in the back gate trench BG_T. For example, the back gate conductive film may fill the back gate trench BG_T. The back gate electrodes BG may be formed to extend in the first direction D1 by etching the back gate conductive film. The back gate electrodes BG may be disposed in the back gate trench BG_T. For example, the back gate electrodes BG may fill a part of the back gate trench BG_T.

According to some embodiments, a gas phase doping (GPD) process or a plasma doping (PLAD) process may be performed before forming the back gate insulating pattern 113, and the active layer 202 exposed by the back gate trench BG_T may be doped with impurities.

The back gate isolation patterns 111 may be formed on the back gate electrode BG.

The back gate isolation pattern 111 may be disposed in the remaining part of the back gate trench BG_T. For example, the back gate isolation pattern 111 may fill the remaining part of the back gate trench BG_T. When the back gate isolation pattern 111 and the back gate insulating pattern 113 are made of the same material (e.g., silicon oxide), the back gate insulating pattern 113 on the upper surface of the mask pattern MP may be removed while the back gate isolation pattern 111 is formed.

A gas phase doping (GPD) process or a plasma doping (PLAD) process may be performed, before forming the back gate isolation pattern 111, and impurities may be doped into the active layer 302 through the back gate trench BG_T in which the back gate electrode BG has been formed.

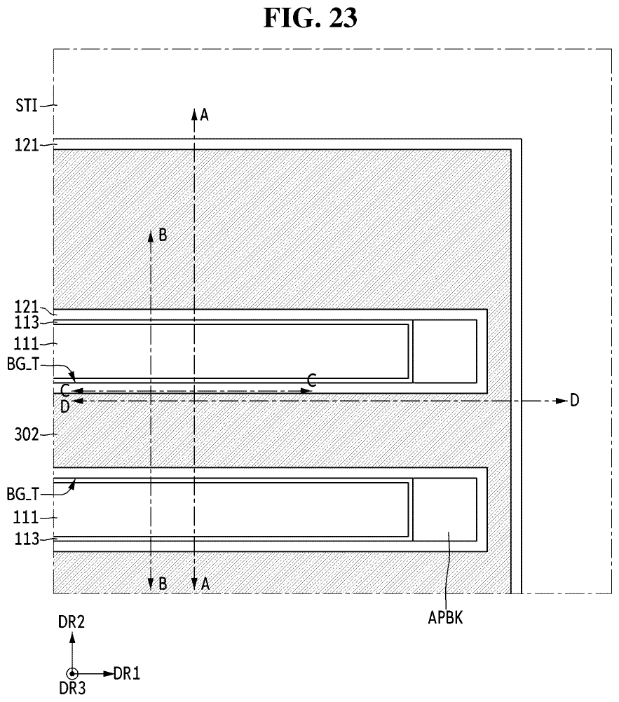

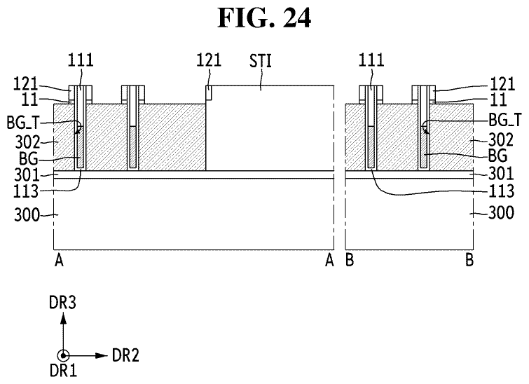

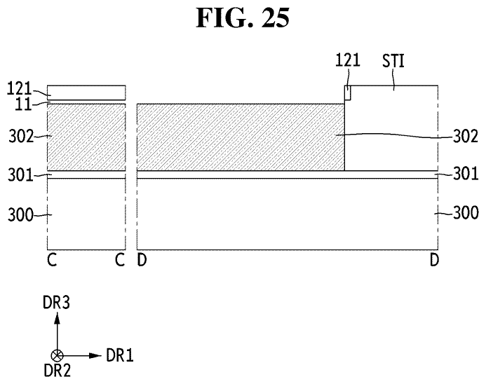

Referring to FIG. 23, FIG. 24, and FIG. 25, after forming the back gate isolation patterns 111, the upper mask film 12 may be removed.

The back gate isolation patterns 111 may have a shape that protrudes upward beyond the upper surface of the lower mask film 11. The active pattern isolation structures APBK may have a shape protruding more upward than the upper surface of the lower mask film 11.

A pair of spacer patterns 121 may be formed on the sidewall of the back gate insulating pattern 113. The spacer pattern 121 may also be formed on the sidewall of the active pattern isolation structure APBK.

While the upper mask film 12 is being removed, the cell region element isolation film STI may be partially removed, and a stepped structure may be formed along the boundary of the active layer 302 of the cell array region CAR. The spacer pattern 121 may be formed on the stepped structure of the cell region element isolation film STI.

More specifically, a spacer film may be formed along the upper surface of the first lower mask film 11, the sidewalls of the back gate insulating patterns 113, and the upper surfaces of the back gate isolation patterns 111. The spacer film may be formed along the sidewall of the active pattern isolation structure APBK and the upper surface of the active pattern isolation structure APBK. The spacer film may be formed to have a uniform thickness. The spacer pattern 121 may be formed by performing an anisotropic etching process on the spacer film. While the spacer pattern 121 is formed, the active layer 302 may be exposed.

Widths of active patterns of vertical channel transistors may be determined according to the deposition thickness of the spacer film. The spacer film may be made of an insulating material. The spacer film may include, for example, silicon oxide, silicon oxynitride, silicon nitride, silicon carbide (SiC), silicon carbon nitride (SiCN), and a combination thereof.

Referring to FIGS. 23 to 28, an anisotropic etching process may be performed on the active layer 302 by using the spacer pattern 121 as an etching mask.

Pre-active patterns PAP extending along the back gate electrode BG may be formed by the anisotropic etching process. As the pre-active patterns PAP are formed, the buried insulating layer 301 may be exposed. The pre-active pattern PAP may be formed along the sidewall of the active pattern isolation structure APBK.

While the pre-active pattern PAP is being formed, a word line trench WL_T is formed.

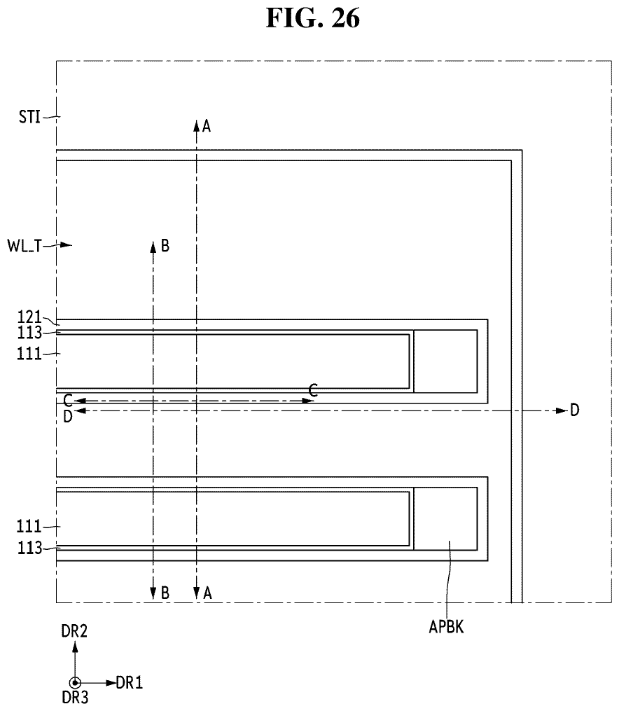

Referring to FIGS. 26 to 31, a sacrificial film may be disposed in the word line trench WL_T.

An active mask pattern may be formed on the sacrificial film. The active mask pattern may have a line shape extending in the second direction D2. As another example, the active mask pattern may have a line shape extending in an oblique direction with respect to the first and second directions DR1 and DR2. Sacrificial openings may be formed in the sacrificial film by etching the sacrificial film using the active mask pattern as an etching mask.

The first active pattern AP1 and the second active pattern AP2 may be formed on both sides of the back gate electrode BG by etching the pre-active patterns PAP exposed through the sacrificial openings. The first active patterns AP1 may be formed on a first sidewall of the back gate electrode BG to be spaced apart from each other in the first direction DR1. The second active patterns AP2 may be formed on a second sidewall of the back gate electrode BG to be spaced apart from each other in the first direction DR1. As the first active pattern AP1 and the second active pattern AP2 are formed, the sacrificial openings may expose a part of the back gate insulating pattern 113.

The sacrificial film, the active mask pattern, the spacer pattern 121 and the lower mask film 11 may be removed, and the first active pattern AP1 and the second active pattern AP2 may be exposed. In addition, the buried insulating layer 301 may be exposed.

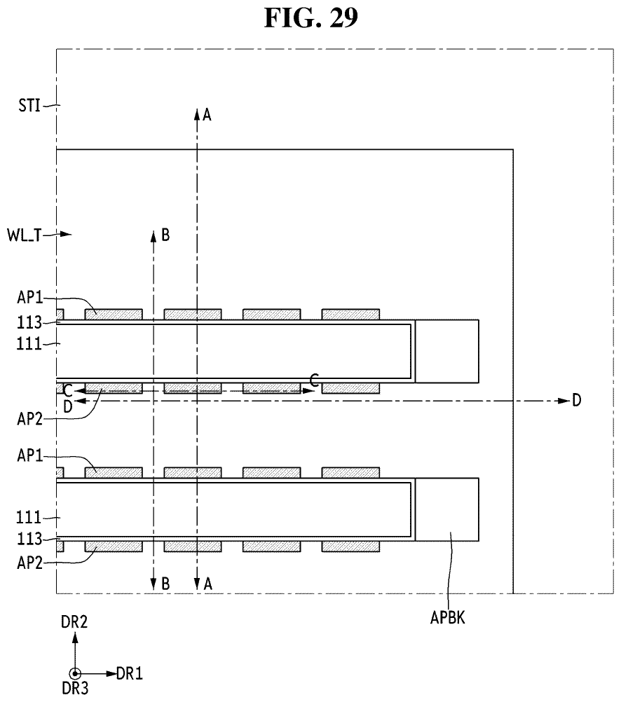

Referring to FIGS. 29 to 34, the gate insulating pattern GOX may be formed along the sidewall of the first active pattern AP1, the sidewall of the second active pattern AP2, and the upper surface of the buried insulating layer 301.

The gate insulating pattern GOX may be formed along the sidewall of the cell region element isolation film STI and the sidewall of the active pattern isolation structure APBK.

The gate insulating pattern GOX may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto.

The first word lines WL1 and the second word lines WL2 may be formed on the gate insulating pattern GOX. The dummy word line WL_D may be formed on the gate insulating pattern GOX. The first word lines WL1 may be formed along the sidewall of the first active patterns AP1. The second word lines WL2 may be formed along the sidewall of the second active patterns AP2. The dummy word line WL_D may be formed along the sidewall of the cell region element isolation film STI.

Forming the first and second word lines WL1 and WL2 and the dummy word line WL_D may include depositing a gate conductive film on the gate insulating pattern GOX and then performing an anisotropic etching process on the gate conductive film. Here, the deposition thickness of the gate conductive film may be smaller than half of the width of the word line trench WL_T. The gate conductive film may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto.

The gate isolation pattern GSS may be formed on the first and second word lines WL1 and WL2 and the dummy word line WL_D. For example, the upper surface of the gate isolation pattern GSS may be disposed on the same plane as the upper surface of the back gate isolation pattern 111.

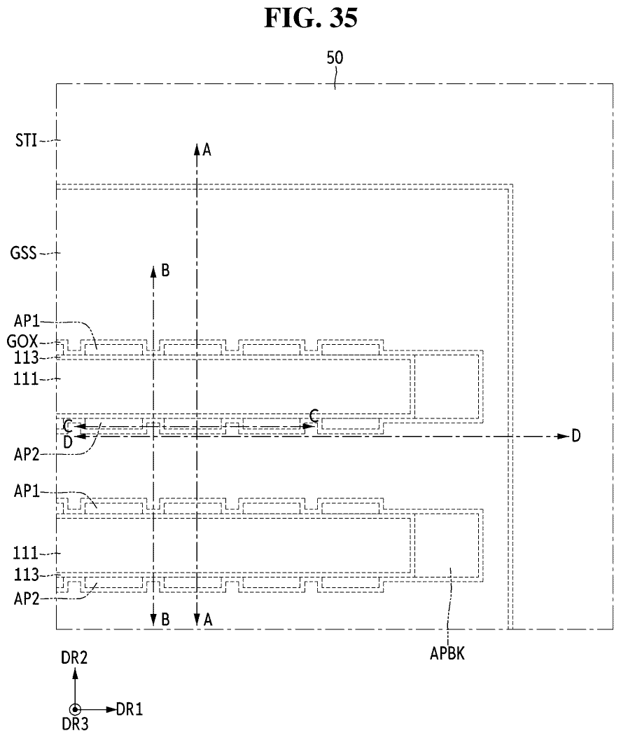

Referring to FIGS. 35 to 37, a pad structure film 50 may be disposed on the first sub-substrate 300.

The pad structure film 50 may be formed across the cell array region CAR and the peripheral circuit region PCR. The pad structure film 50 may be formed on the gate isolation pattern GSS and the cell region element isolation film STI.

The pad structure film 50 may include a contact film 51 and a sacrificial pad film 52. The contact film 51 may be formed on the gate isolation pattern GSS and the cell region element isolation film STI. The contact film 51 may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto. The sacrificial pad film 52 may be formed on the contact film 51. The sacrificial pad film 52 may include an insulating material. The sacrificial pad film 52 may include a material having an etching selectivity with respect to the pad isolation pattern 245 (see FIG. 3, FIG. 4, and FIG. 5). When the pad isolation pattern 245 includes silicon nitride, the sacrificial pad film 52 may include silicon oxide.

Referring to FIGS. 35 to 40, the pad structure film 50 may be patterned to form a pad structure pattern 55.

The pad structure pattern 55 may be formed on the cell array region CAR. The pad structure pattern 55 may exposed the cell region element isolation film STI. In plan view, the sidewall of the pad structure pattern 55 may have a zigzag shape including alternating protruding portions and recessed portions.

The pad structure pattern 55 may include a contact structure pattern 56 and a first sacrificial pad pattern 57. The contact structure pattern 56 may be formed by patterning the contact film 51. The first sacrificial pad pattern 57 may be formed by patterning the sacrificial pad film 52.

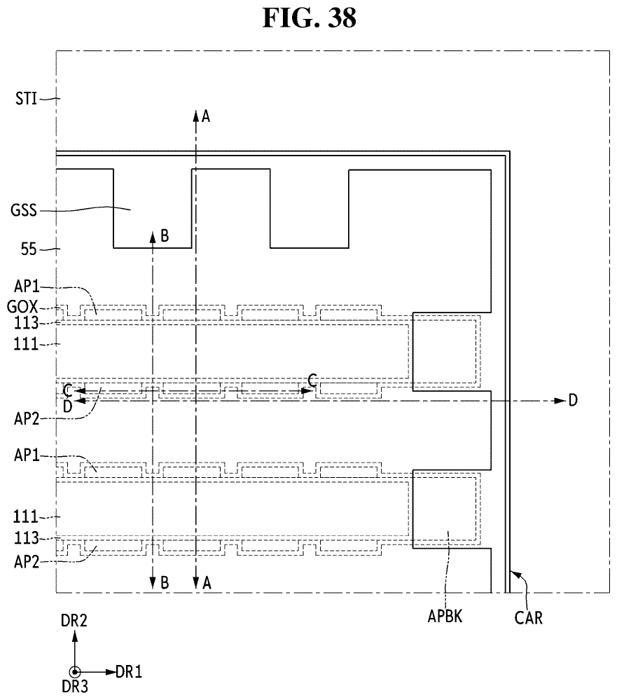

Referring to FIGS. 38 to 43, the outer pad isolation pattern 245_O may be formed on the cell region element isolation film STI and the gate isolation pattern GSS.

The outer pad isolation pattern 245_O may be formed on the sidewall of the pad structure pattern 55. The outer pad isolation pattern 245_O may be disposed in the recessed portions of the pad structure pattern 55. For example, the outer pad isolation pattern 245_O may fill the recessed portions of the pad structure pattern 55. In plan view, the outer pad isolation pattern 245_O may include an inner wall facing the pad structure pattern 55 and an outer wall opposite the inner wall of the outer pad isolation pattern 245_O. The outer wall of the outer pad isolation pattern 245_O is shown as having a square or rectangular shape, but it is not limited thereto.

The outer pad isolation pattern 245_O may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto.

The first interlayer insulating film 290 may be formed on the outer wall of the outer pad isolation pattern 245_O.

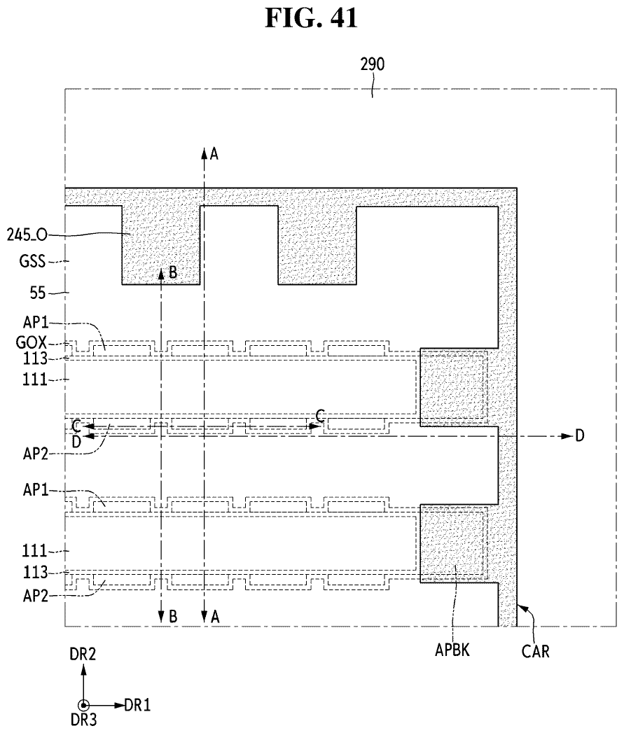

Referring to FIGS. 41 to 46, the pad structure pattern 55 may be patterned to form the contact patterns BC, the first contact block patterns BCB_1, the second contact block patterns BCB_2, and second sacrificial pad patterns 58.

The edge contact block patterns BCB_E (see FIG. 50) may be formed by patterning the pad structure pattern 55.

The contact patterns BC, the first contact block patterns BCB_1, the second contact block patterns BCB_2, and the edge contact block patterns BCB_E (see FIG. 50) may be formed by patterning the contact structure pattern 56. The second sacrificial pad patterns 58 may be formed by patterning the first sacrificial pad pattern 57. The second sacrificial pad patterns 58 may be formed on the contact patterns BC, the first contact block patterns BCB_1, the second contact block patterns BCB_2, and the edge contact block patterns BCB_E (see FIG. 50) corresponding thereto.

The contact patterns BC, the first contact block patterns BCB_1, the second contact block patterns BCB_2, and the edge contact block patterns BCB_E (see FIG. 50) may be spaced apart from each other. A contact isolation space may be formed between the contact patterns BC, the first contact block patterns BCB_1, the second contact block patterns BCB_2, and the edge contact block patterns BCB_E (see FIG. 50). The contact isolation space may correspond to a space where the pad isolation pattern 245 is disposed. For example, the outer pad isolation pattern 245_O may be separated from the contact patterns BC by the contact isolation space portion in which the inner pad isolation pattern 245_I is disposed. The contact isolation space may be formed in the cell array region CAR.

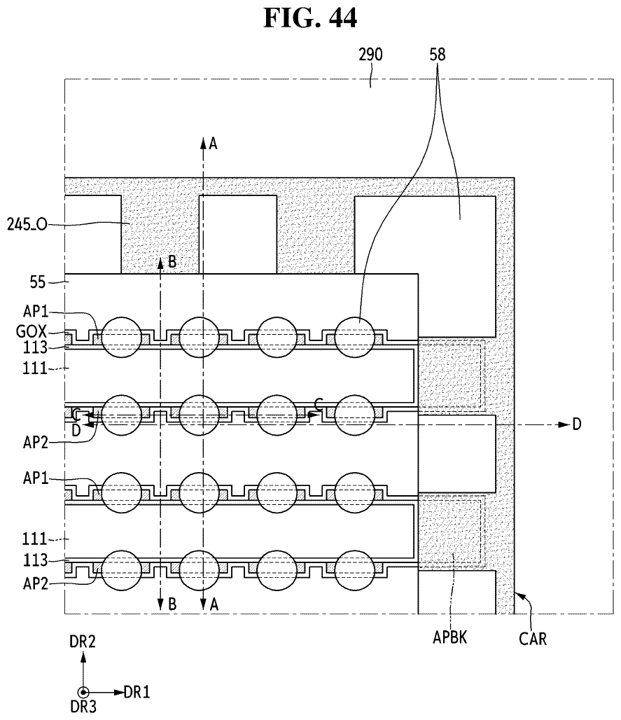

Referring to FIGS. 44 to 49, the inner pad isolation pattern 245_I may be formed in the cell array region CAR.

The inner pad isolation pattern 245_I may be disposed in a portion of the contact isolation space. The inner pad isolation pattern 245_I may fill the contact isolation space, and the pad isolation pattern 245 including the inner pad isolation pattern 245_I and the outer pad isolation pattern 245_O may be formed.

The inner pad isolation pattern 245_I may be formed using at least one of a physical vapor deposition (PVD) method, a thermal chemical vapor deposition (thermal CVD) method, a low pressure chemical vapor deposition (LPCVD) method, a plasma enhanced chemical vapor deposition (PECVD) method, or an atomic layer deposition (ALD) method. However, the present disclosure is not limited thereto.

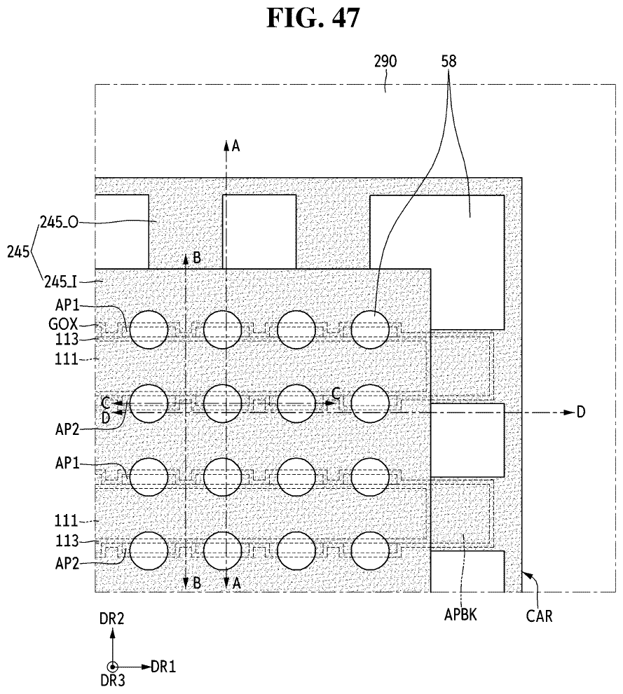

Referring to FIGS. 47 to 52, a cell open mask MASK may be formed on the pad isolation pattern 245 and the first interlayer insulating film 290.

The cell open mask MASK may be formed on the peripheral circuit region PCR. The cell open mask MASK may expose at least a part of the cell array region CAR.

For example, the cell open mask MASK may expose the second sacrificial pad patterns 58 on the contact patterns BC. The cell open mask MASK may expose at least a part of the second sacrificial pad patterns 58 on the first contact block patterns BCB_1, the second contact block patterns BCB_2, and the edge contact block patterns BCB_E. The cell open mask MASK may not expose the first interlayer insulating film 290. For example, the cell open mask MASK may cover the first interlayer insulating film 290.

The second sacrificial pad pattern 58 may be removed using the cell open mask MASK as an etching mask, and the contact patterns BC, the first contact block patterns BCB_1, the second contact block patterns BCB_2, and the edge contact block patterns BCB_E may be exposed.

Referring to FIGS. 50 to 55, after removing the cell open mask MASK, the landing pads LP, the first pad block patterns LPB_1, the second pad block pattern LPB_2, and the edge pad block patterns LPB_E may be formed in the pad isolation pattern 245.

The landing pads LP may be formed on the contact patterns BC. The landing pads LP may be formed at locations corresponding to the contact patterns BC. The first pad block patterns LPB_1 may be formed on the first contact block patterns BCB_1. The second pad block patterns LPB_2 may be formed on the second contact block patterns BCB_2. The edge pad block patterns LPB_E may be formed on the edge contact block patterns BCB_E. For example, the first pad block patterns LPB_1 may correspond to the first contact block patterns BCB_1, the second pad block patterns LPB_2 may correspond to the second contact block patterns BCB_2, and the edge pad block patterns LPB_E may correspond to the edge contact block patterns BCB_E.

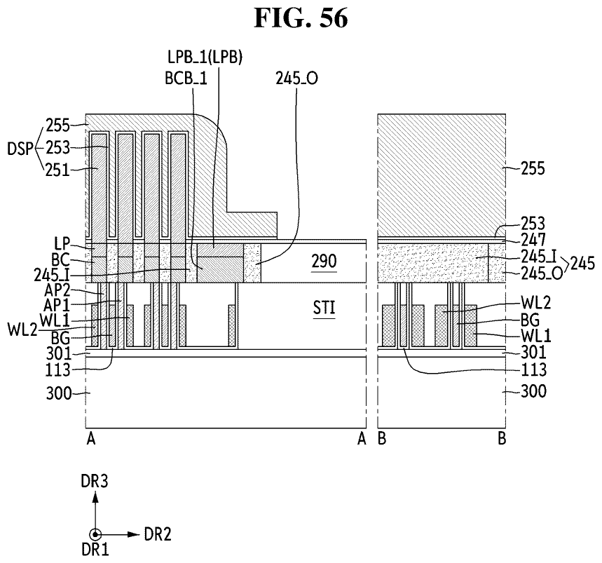

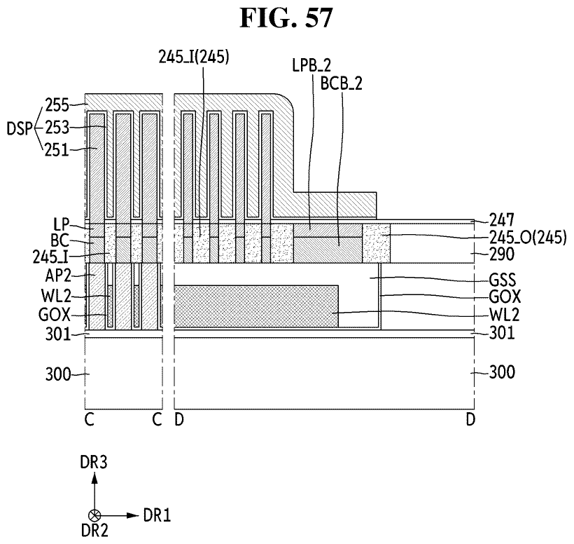

Referring to FIGS. 56 and 57, the etch stop film 247 may be formed on the landing pads LP, the pad block patterns LPB, and the pad isolation pattern 245.

The storage electrode 251 may be formed on the landing pad LP by penetrating the etch stop film 247. The capacitor dielectric film 253 and the plate electrode 255 may be formed on the storage electrode 251, and the data storage patterns DSP may be formed on the landing pads LP. The data storage patterns DSP may be connected to the first active pattern AP1 and the second active pattern AP2.

Referring to FIGS. 56 to 59, the second interlayer insulating film 291 may be formed on the data storage patterns DSP.

The first sub-substrate 300, on which the back gate electrodes BG, the first and second word lines WL1 and WL2, the first and second active patterns AP1 and AP2, and the data storage patterns DSP are formed, may be bonded to a second sub-substrate 400.

For example, the back gate electrodes BG, the first and second word lines WL1 and WL2, the first and second active patterns AP1 and AP2, and the data storage patterns DSP may be an intermediate structure disposed between the first sub-substrate 300 and the second sub-substrate 400.

The first sub-substrate 300 and the second sub-substrate 400 may be bonded to the intermediate structure using a bonding adhesive film.

As an example, the second sub-substrate 400 may be a semiconductor substrate. As another example, the second sub-substrate 400 may be an insulating substrate including an insulating material.

With the second sub-substrate 400 bonded to the intermediate structure, a backside lapping process of removing the first sub-substrate 300 may be performed.

Removing the first sub-substrate 300 may include exposing the buried insulating layer 301 by sequentially performing a grinding process and a wet etching process.

With the first sub-substrate 300 removed, the first active pattern AP1 and the second active pattern AP2 may be exposed by removing the buried insulating layer 301. As the buried insulating layer 301 is removed, a part of the back gate insulating pattern 113 may be exposed.

The exposed part of the back gate insulating pattern 113 may be removed. For example, the back gate electrode BG may be exposed by the removal of the back gate insulating pattern 113.

A part of the back gate electrode BG may be removed by performing an etch-back process. The back gate capping pattern 115 may be formed on the recessed back gate electrode BG.

The bit line BL extending in the second direction DR2 may be formed on the first active pattern AP1 and the second active pattern AP2. The shielding conductive pattern SL may be formed on the bit line BL. The shielding insulating capping film 175 may be formed on the shielding conductive pattern SL.

The first cell interlayer insulating film 271 may be formed on the shielding insulating liner 171. The first cell interlayer insulating film 271 may cover the sidewall of the shielding conductive pattern SL.

The bit line contact plug 281a and the word line contact plug 281b may be formed. The bit line contact plug 281a may be formed on the bit lines BL. The word line contact plug 281b may be formed on the first and second word lines WL1 and WL2.

The second cell interlayer insulating film 272 may be formed on the first cell interlayer insulating film 271, the bit line contact plug 281a, and the word line contact plug 281b. The first cell connection line 281 may be formed in the second cell interlayer insulating film 272. At least a part of the first cell connection lines 281 may be connected to the bit line contact plug 281a and the word line contact plug 281b.

The third cell interlayer insulating film 273, the fourth cell interlayer insulating film 274, and the fifth cell interlayer insulating film 275 may be formed on the second cell interlayer insulating film 272. The upper pad plug BPPG2 and the upper bonding pad BP2 may be formed in the fifth cell interlayer insulating film 275.

Referring to FIG. 4 and FIG. 5, the substrate 100, on which the first peri-gate structure PG1, the first peri-connection structure including the first peri-connection via 242a and the first peri-connection line 242b, the lower bonding pad BP1, and the lower pad plug BPPG1 are formed, may be bonded to a sub-structure supported by the second sub-substrate 400. For example, the sub-structure supported by the second sub-substrate 400 may be disposed between the substrate 100 and the second sub-substrate 400.

With the substrate 100 bonded to the sub-structure, the second sub-substrate 300 may be removed.

In concluding the detailed description, those skilled in the art will appreciate that many variations and modifications may be made to embodiments without substantially departing from the principles of the present inventive concept. Therefore, embodiments of the disclosure are used in a generic and descriptive sense only and not for purposes of limitation.

What is claimed is:

1. A semiconductor memory device comprising:
a cell region element isolation film disposed on a substrate and defining a cell array region;
a first active pattern and a second active pattern disposed in the cell array region and alternately disposed along a first direction;
a pad isolation pattern disposed on the cell region element isolation film, the first active pattern, and the second active pattern;
a plurality of landing pads disposed in the pad isolation pattern and connected to the first active pattern and the second active pattern;
a plurality of pad block patterns disposed in the pad isolation pattern and disposed along a perimeter defined by the plurality of landing pads; and
a plurality of data storage patterns disposed on the plurality of landing pads.

2. The semiconductor memory device of claim 1, wherein the cell region element isolation film comprises a first cell region sidewall extending in a first direction and a second cell region sidewall extending in a second direction crossing the first direction, the first cell region sidewall and the second cell region sidewall defining the cell array region,
the plurality of pad block patterns comprise a first pad block group and a second pad block group,
the first pad block group comprises a plurality of first pad block patterns arranged along the first cell region sidewall, and
the second pad block group comprises a plurality of second pad block patterns arranged along the second cell region sidewall.

3. The semiconductor memory device of claim 2, wherein the pad block patterns further comprise a plurality of edge pad block patterns, and
an edge pad block pattern of the plurality of edge pad block patterns is disposed proximate to a corner where the first cell region sidewall and the second cell region sidewall meet.

4. The semiconductor memory device of claim 1, wherein the plurality of pad block patterns are disconnected from the first active pattern and the second active pattern.

5. The semiconductor memory device of claim 1, wherein the plurality of data storage patterns are respectively connected to the plurality of landing pads.

6. The semiconductor memory device of claim 1, wherein the plurality of landing pads comprise a first landing pad and a second landing pad,
the first landing pad is connected to the data storage pattern, and
the second landing pad is not connected to the data storage pattern.

7. The semiconductor memory device of claim 1, further comprising a plurality of contact patterns disposed between the plurality of landing pads and the first active pattern and the second active pattern.

8. The semiconductor memory device of claim 7, wherein a thickness of the pad isolation pattern in a vertical direction is equal to or greater than a sum of a thickness of a landing pad of the plurality of landing pads in the vertical direction and a thickness of a contact pattern of the plurality of contact patterns in the vertical direction.

9. The semiconductor memory device of claim 1, further comprising a bit line extending in the first direction,
wherein the cell region element isolation film is disposed on the bit line, and
the first active pattern and the second active pattern are connected to the bit line.

10. The semiconductor memory device of claim 1, further comprising:
a back gate electrode disposed in the cell array region and extending in a second direction; and
a word line extending in the second direction and spaced apart from the back gate electrode in the first direction,
wherein the first active pattern comprises a first sidewall and a second sidewall which are opposite to each other in the first direction,
the back gate electrode is disposed on the first sidewall of the first active pattern, and
the word line is disposed on the second sidewall of the first active pattern.

11. A semiconductor memory device comprising:
a cell region element isolation film disposed on a substrate and defining a cell array region;
a plurality of active patterns disposed in the cell array region and disposed along a first direction and a second direction crossing the first direction;
a pad isolation pattern disposed on the cell region element isolation film and the plurality of active patterns and comprising an inner pad isolation pattern and an outer pad isolation pattern, the outer pad isolation pattern surrounding the inner pad isolation pattern and being in contact with the inner pad isolation pattern;
a plurality of landing pads disposed in the inner pad isolation pattern and respectively connected to the plurality of active patterns;
a plurality of pad block patterns disposed in the pad isolation pattern, each of the plurality of pad block patterns being disposed between the inner pad isolation pattern and the outer pad isolation pattern; and
a plurality of data storage patterns disposed on the plurality of landing pads.

12. The semiconductor memory device of claim 11, wherein the plurality of landing pads are isolated from the outer pad isolation pattern by the inner pad isolation pattern.

13. The semiconductor memory device of claim 11, wherein the pad block patterns are separated from each other by the outer pad isolation pattern and are in contact with the inner pad isolation pattern.

14. The semiconductor memory device of claim 11, wherein the plurality of pad block patterns comprise a first pad block group and a second pad block group,
the first pad block group comprises a plurality of first pad block patterns arranged along the first direction, and
the second pad block group comprises a plurality of second pad block patterns arranged along the second direction.

15. The semiconductor memory device of claim 14, wherein the plurality of pad block patterns further comprise a plurality of edge pad block patterns,
the cell region element isolation film comprises a first cell region sidewall extending in the first direction and a second cell region sidewall extending in the second direction, and
each edge pad block pattern of the plurality of edge pad block patterns is disposed proximate to a corner where the first cell region sidewall and the second cell region sidewall meet.

16. The semiconductor memory device of claim 11, further comprising a plurality of bit lines extending in the first direction,
wherein the cell region element isolation film is disposed on the plurality of bit lines, and
each bit line of the plurality of bit lines is connected to an active pattern of the plurality of active patterns arranged along the first direction.

17. The semiconductor memory device of claim 16, further comprising:
a back gate electrode disposed in the cell array region and extending in the second direction; and
a word line extending in the second direction and spaced apart from the back gate electrode in the first direction,
wherein the active pattern comprises a first sidewall and a second sidewall which are opposite to each other in the first direction,
the back gate electrode is disposed on the first sidewall of the active pattern, and
the word line is disposed on the second sidewall of the active pattern.

18. A semiconductor memory device comprising:
a plurality of bit lines disposed on a substrate and extending in a first direction;
a cell region element isolation film disposed on the plurality of bit lines and defining a cell array region;
a first back gate electrode and a second back gate electrode disposed in the cell array region on the substrate, arranged in the first direction, and extending in a second direction;
a first word line and a second word line disposed between the first back gate electrode and the second back gate electrode adjacent in the first direction and extending in the second direction;
a plurality of first active patterns disposed between the first back gate electrode and the first word line and arranged in the second direction;
a plurality of second active patterns disposed between the second back gate electrode and the second word line and arranged in the second direction;
a pad isolation pattern disposed on the cell region element isolation film, the plurality of first active patterns and the plurality of second active patterns;
a plurality of landing pads disposed in the pad isolation pattern and respectively connected to the plurality of first active patterns and the plurality of second active patterns;
a plurality of pad block patterns disposed in the pad isolation pattern and disposed along perimeters of the landing pads; and
a plurality of data storage patterns disposed on the plurality of landing pads,
wherein the pad block patterns comprise a plurality of first pad block patterns arranged along the first direction and a plurality of second pad block patterns arranged along the second direction.

19. The semiconductor memory device of claim 18, wherein the pad isolation pattern comprises an inner pad isolation pattern surrounding the plurality of landing pads and an outer pad isolation pattern surrounding the inner pad isolation pattern,
the outer pad isolation pattern is in contact with the inner pad isolation pattern, and
the plurality of first pad block patterns and the plurality of second pad block patterns are disposed along a boundary between the inner pad isolation pattern and the outer pad isolation pattern.

20. The semiconductor memory device of claim 18, wherein the pad block patterns are disconnected from the first active pattern and the second active pattern.
